(19) United States
(12) Patent Application Publication
(10) Pub. No.: US 2024/0321759 A1
(43) Pub. Date: Sep. 26, 2024

(54) PACKAGE STRUCTURE INCLUDING LOWER MOLDED STRUCTURE INCLUDING A SUBSTRATE PORTION, AND METHODS OF FORMING THE PACKAGE STRUCTURE

(71) Applicant: Taiwan Semiconductor Manufacturing Company Limited, Hsinchu (TW)

(72) Inventors: Tsung-Ding Wang, Tainan (TW); Chien-Hsun Lee, Hsinchu (TW); Shang-Yun Hou, Jubei City (TW); Hao-Cheng Hou, Hsinchu City (TW); Chin-Liang Chen, Kaohsiung City (TW)

(21) Appl. No.: 18/344,900

(22) Filed: Jun. 30, 2023

Related U.S. Application Data
(60) Provisional application No. 63/453,848, filed on Mar. 22, 2023.

(51) Int. Cl. H01L 23/538; H01L 21/48; H01L 21/56; H01L 23/00; H01L 23/31; H01L 23/498; H01L 25/10

(52) U.S. Cl. CPC H01L 23/5386; H01L 21/4853; H01L 21/4857; H01L 21/563; H01L 21/565; H01L 21/568; H01L 23/3135; H01L 23/49816; H01L 23/49822; H01L 23/49833; H01L 23/49838; H01L 23/5381; H01L 23/5384; H01L 23/5385; H01L 24/16; H01L 24/32; H01L 24/73; H01L 25/105; H01L 23/3675; H01L 2224/16227; H01L 2224/16238; H01L 2224/32225; H01L 2224/73204; H01L 2225/1023; H01L 2225/1041; H01L 2225/1058; H01L 2225/107; H01L 2225/1094; H01L 2924/1427; H01L 2924/1431; H01L 2924/1434; H01L 2924/3511

(57) ABSTRACT

A package structure includes an interposer including a front side and a back side opposite the front side, an upper molded structure on the front side of the interposer and including an upper molding layer and a semiconductor die in the upper molding layer, and a lower molded structure on the back side of the interposer and including a lower molding layer and a substrate portion in the lower molding layer, wherein the substrate portion includes conductive layers electrically coupled to the semiconductor die through the interposer.

### RELATED APPLICATIONS

This application claims priority from U.S. Provisional Application Ser. No. 63/453,848 entitled “Semiconductor Package and Method of Manufacturing the Same,” filed on Mar. 22, 2023, the entire contents of which are incorporated herein by reference for all purposes.

### BACKGROUND

The term “system on wafer” (SoW) may refer to a technique where an entire electronic system or subsystem is integrated onto a single wafer, instead of building individual components and then assembling them into a package. This approach is also known as “wafer-level integration.”

With SoW, an entire electronic system may be built on a single wafer, including, for example, the microcontroller, memory, power management, and other necessary components. This approach offers several advantages, including smaller size, higher performance, and lower cost, as there are fewer assembly steps and less material waste. SoW technology may provide a promising technology for high-performance and high-density electronic systems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a package structure (e.g., semiconductor package) according to one or more embodiments.

FIG. 2A is a bottom-up view of the substantially planar lower surface of the lower molding layer, according to one or more embodiments.

FIG. 2B is a detailed cross-sectional view of a portion of the lower molding layer including the second substrate portion, according to one or more embodiments.

FIG. 3A is a vertical cross-sectional view of an intermediate structure including the front-side RDL interposer portion formed on a first carrier substrate (e.g., carrier wafer) according to one or more embodiments.

FIG. 3B is a vertical cross-sectional view of an intermediate structure including the LSI die according to one or more embodiments.

FIG. 3C is a vertical cross-sectional view of an intermediate structure including the molding material layer according to one or more embodiments.

FIG. 3D is a vertical cross-sectional view of an intermediate structure including the back-side RDL interposer portion on the molded interposer portion according to one or more embodiments.

FIG. 3E is a vertical cross-sectional view of an intermediate structure including the interposer on a second carrier substrate according to one or more embodiments.

FIG. 3F is a vertical cross-sectional view of an intermediate structure including the first semiconductor dies on the interposer according to one or more embodiments.

FIG. 3G is a vertical cross-sectional view of an intermediate structure including the package underfill layer according to one or more embodiments.

FIG. 3H illustrates a vertical cross-sectional view of an intermediate structure including the upper molding material according to one or more embodiments.

FIG. 3I is a vertical cross-sectional view of an intermediate structure including the interposer and the upper molding layer on a third carrier substrate according to one or more embodiments.

FIG. 3J illustrates a vertical cross-sectional view of an intermediate structure including the substrate portions, according to one or more embodiments.

FIG. 3K illustrates a vertical cross-sectional view of an intermediate structure including the lower molding material according to one or more embodiments.

FIG. 3L illustrates a vertical cross-sectional view of an intermediate structure including the components and connectors, according to one or more embodiments.

FIG. 4 is a flow chart illustrating a method of forming the package structure according to one or more embodiments.

FIG. 5 is a vertical cross-sectional view of the package structure having a first alternative design according to one or more embodiments.

FIG. 6 is a vertical cross-sectional view of the package structure having a second alternative design according to one or more embodiments.

FIG. 7 is a bottom-up view of the substantially planar lower surface of the lower molding layer having a first alternative design, according to one or more embodiments.

FIG. 8 is a bottom-up view of the substantially planar lower surface of the lower molding layer having a second alternative design, according to one or more embodiments.

FIG. 9 is a vertical cross-sectional view of the package structure having a third alternative design according to one or more embodiments.

FIG. 10 is a vertical cross-sectional view of a package structure having a fourth alternative design according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A package structure (semiconductor package) may include an interposer and one or more semiconductor dies (e.g., top dies) on the interposer. The interposer may include a fan-out wafer including a redistribution layer (RDL) structure (e.g., fan-out wafer). The semiconductor dies may include, for example, silicon dies including as logic dies, memory dies, or the like. An encapsulant may be formed around the semiconductor dies. The encapsulant may include, for example, molding material, dielectric material, or the like and may or may not include filler material.

The package structure may also include connectors and other components (e.g., bottom components) on the interposer opposite the semiconductor dies. The connectors may include, for example, solder balls, bumps, connectors with pins, socket connectors, etc. The other components may include, for example, various logic components, memory components, passive component, etc.). In particular, the components may include one or more voltage regulator modules (VRMs).

The package structure may be manufactured by a method (e.g., chip-first approach) including placing the semiconductor dies on a carrier (e.g., using an electromechanical pick-and-place machine). Over-molding and planarizing may then be performed to reveal the semiconductor dies. The interposer (e.g., fan-out (F/O) wafer) including the RDL structure with a silicon bridge may then be formed over the molded semiconductor dies. The structure may then be flipped over and the carrier debonded. The components and connectors may then be mounted on the interposer by solder joints.

Problems may occur during the bonding/mounting process of the semiconductor dies or the bottom components to the interposer (F/O wafer) due to the mismatch of coefficient of thermal expansion (CTE) between the semiconductor dies, the interposer and the bottom components may lead to wafer warpage and package stress issues, thereby impacting the reliability of entire package.

One or more embodiments of the present disclosure may include a package structure and method of manufacturing the package structure that mitigate problems that may occur due to the mismatch of CTE. The package structure may be provided with a stacked 3-dimensional (3D) structures. For example, 3D stacked structures may include, but are not limited to chip-on-wafer-on-substrate plus LSI die technology (CoWoS L+) for system on wafer (SoW) application. The SoW application may enable wafer-level system integration to fulfill a high-performance computing (HPC) requirement. The package structure may adequately address the current challenges in processes such as wafer warpage and reliability (e.g., package stress).

The package structure may overcome process and reliability concerns in SoW, by including 1) an interposer having multiple RDL layers for chip interconnection and a package stress buffer, and 2) a discrete substrate such as a light organic substrate bonded to the interposer to compensate for wafer CTE mismatch and reduce wafer warpage. The package structure may also include molding material at a front-side of the interposer, the light organic substrate (with or without a dummy unit) at a back-side of the interposer, and a molding material at a back-side of the interposer for the light organic substrate (with or without a dummy unit).

The package structure may have several advantages. The package stress in silicon may be buffered by including multiple RDL layers in the interposer. Wafer warpage may be improved by adding the substrate bonding. The package structure (e.g., final structure) may also be compatible with current processes (e.g., SoW technology would like to adopt local silicon interconnect (LSI) bridges to connect SoC/high-bandwidth memory (HBM)/Chiplets).

The package structure may be manufactured, for example, by a method (e.g., chip last approach) including forming (e.g., by RDL formation) the interposer (F/O wafer) including the RDL structure with a silicon bridge on a first carrier (e.g., carrier wafer). The package structure may then be flipped over, the first carrier debonded, and the package structure bonded to a second carrier. The semiconductor dies may then be placed on the interposer (e.g., using an electromechanical pick-and-place machine). An underfill layer may then optionally be dispensed under the semiconductor dies. Over-molding and planarizing may then be performed to reveal the semiconductor dies. The package structure may then be flipped over, the second carrier debonded, and the package structure placed on a third carrier. One or more light organic substrates may then be placed on the interposer. One or more dummy units may also be mounted onto the interposer. The third carrier may then be debonded and the components and connectors may be bonded to the light organic substrate(s) (and the dummy unit(s)) by solder joints.

In at least one embodiment, a package structure may include a circuit substrate (interposer), a plurality of semiconductor dies disposed on and electrically coupled to the circuit substrate (interposer), a supporting structure (substrate portion), disposed on and electrically coupled to the circuit substrate (interposer), wherein the circuit substrate (interposer) is interposed between the semiconductor dies and the supporting structure (substrate portion), a first insulating encapsulation (lower molding material) encapsulating the supporting structure (substrate portion) and covering the circuit substrate (interposer) exposed by the supporting structure (substrate portion), and a second insulating encapsulation (upper molding material) encapsulating the semiconductor dies and covering the circuit substrate (interposer) exposed by the semiconductor dies. The package structure may further include one or more connectors, disposed on and electrically coupled to the supporting structure (substrate portion), the supporting structure (substrate portion) being between the circuit substrate (interposer) and the connectors. The package structure may further include a plurality of semiconductor devices (components), disposed on and electrically coupled to the supporting structure (substrate portion), the supporting structure (substrate portion) being between the circuit substrate (interposer) and the semiconductor devices (components). The plurality of connectors and the plurality of semiconductor devices (components) may be disposed at a side of the at least one supporting structure (substrate portion).

In at least one embodiment, the circuit substrate (interposer) may include at least one bridge die (LSI die) embedded therein. Further, the supporting structure (substrate portion) may include a plurality of auxiliary circuit substrates, and each of the plurality of auxiliary circuit substrates independently may include a core layer (core) with a redistribution structure (metal interconnect structure) disposed at one side thereof, a core layer (core) with a pair of redistribution structures (metal interconnect structures) respectively disposed at opposite sides thereof, or a redistribution structure (metal interconnect structure).

The package structure may have many applications including, for example, general technology (e.g., ASIC wafers), stacking wafer technology, and so on. In particular, the package structure may have general applications such as automotive, server, artificial intelligence (AI), NIR, event sensor, III-V image sensor, global shutter, etc.

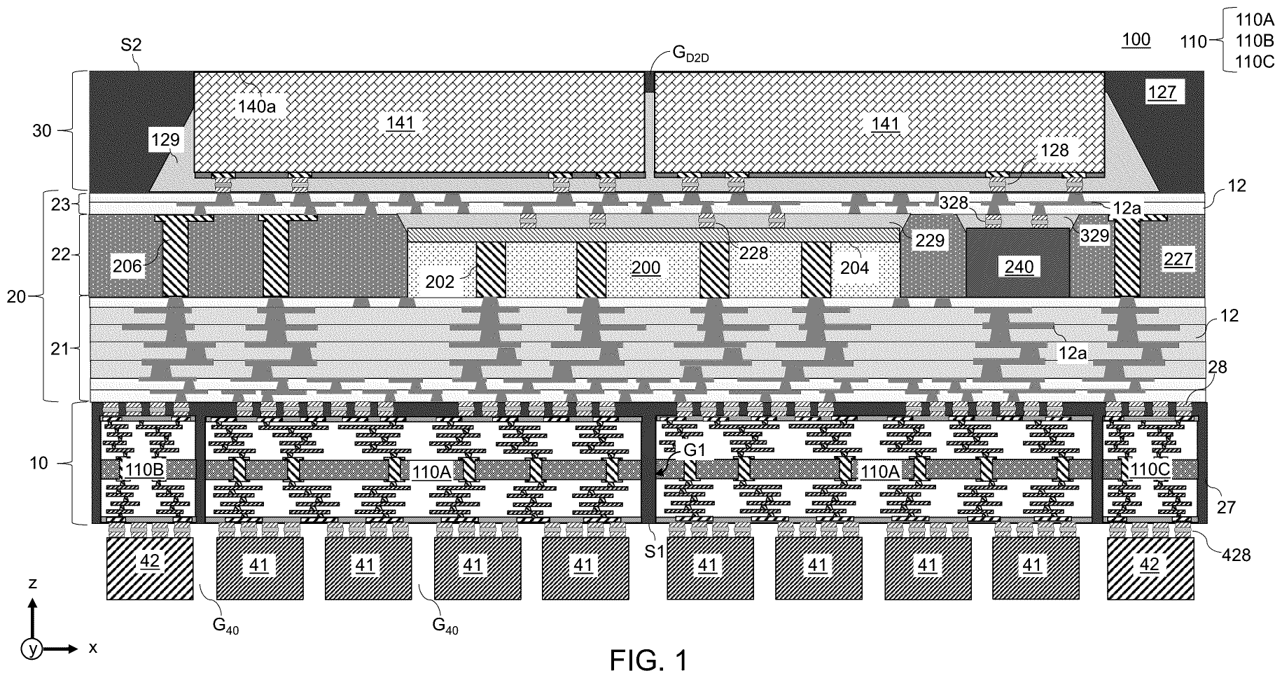

FIG. 1 is a vertical cross-sectional view of a package structure 100 (e.g., semiconductor package) according to one or more embodiments. As illustrated in FIG. 1, the package structure 100 may include a lower molded structure 10. The package structure 100 may also include one or more components 41 and connectors 42 on the lower molded structure 10. The package structure 100 may also include an interposer 20 (e.g., super carrier interposer) on the lower molded structure 10 opposite the one or more components 41 and connectors 42. The package structure 100 may also include an upper molded structure 30 on the interposer 20. The upper molded structure 30 may include one or more first semiconductor dies 141 in an upper molding layer 127.

In at least one embodiment, the lower molded structure 10 may have a first thickness and the interposer 20 may have a second thickness that may be less than the first thickness. In at least one embodiment, the upper molded structure 30 may have a third thickness that is less than the first thickness of the lower molded structure 10 and greater than the second thickness of the interposer 20.

The package structure 100 may have a substantially balanced coefficient of thermal expansion (CTE). This may allow the package structure 100 to mitigate a wafer warpage. In at least one embodiment, the lower molded structure 10 may have a first coefficient of thermal expansion (CTE) and the interposer 20 may have a second CTE greater than the first CTE of the lower molded structure 10. In at least one embodiment, the upper molded structure 30 may have a third CTE less than the first CTE of the lower molded structure 10. In at least one embodiment, a difference between the second CTE of the interposer 20 and the third CTE of the upper molded structure 30 may be less than 15 ppm.

In at least one embodiment, the lower molded structure 10 (e.g., economic substrate) may have a first thickness (in the z-direction) in a range from 800 μm to 2000 μm (e.g., about 1400 μm). The first CTE of the lower molded structure 10 may be in a range from 5 ppm to 15 ppm (e.g., about 9 ppm to 12 ppm). The interposer 20 (e.g., fan-out (F/O) wafer) may have a second thickness in a range from 80 μm to 400 μm (e.g., about 300 μm). The second CTE of the interposer 20 may be in a range from 10 ppm to 25 ppm (e.g., about 15 ppm to 19 ppm). The upper molded structure 30 may have a third thickness in a range from 200 μm to 1000 μm (e.g., about 800 μm). The third CTE of the upper molded structure 30 may be in a range from 2 ppm to 10 ppm (e.g., about 6 ppm. The one or more components 41 and connectors 42 may have a thickness in a range from 1 mm to 5 mm and a CTE in a range from about 5 ppm to 15 ppm (e.g., about 10 ppm).

It should be noted that the thickness values listed above for the lower molded structure 10, interposer 20, upper molded structure 30 and components 41 and connectors 42 should not be considered limiting but are intended only to provide an example of thicknesses in the package structure 100. Thickness values other than those listed above are within the contemplated scope of disclosure.

It should also be noted that the CTE values listed above for the lower molded structure 10, interposer 20, upper molded structure 30, components 41 and connectors 42 may be approximate and based on a volume-weighted average of CTE values of the materials included therein. The CTE values should not be considered limiting but are intended only to provide an example of how the CTE in the package structure 100 may be balanced between a top side of the package structure 100 (e.g., the side of the upper molded structure 30) and a bottom side of the package structure 100 (e.g., the side of the lower molded structure 10). CTE values other than those listed above are within the contemplated scope of disclosure.

The lower molded structure 10 may include one or more substrate portions 110A, 110B and 110C in a lower molding layer 27. The substrate portions 110A, 110B and 110C may be referred to collectively as substrate portions 110. Although four substrate portions 110 (e.g., two substrate portions 110A, one substrate portion 110B and one substrate portion 110C) are shown in FIG. 1 having a particular size and a particular arrangement, the package structure 100 is not limited to any particular number, size or arrangement of the substrate portions 110. That is, the lower molded structure 10 may include any number of substrate portions 110 having any size and any arrangement.

It should also be noted that one or more of the substrate portions 110 in the lower molded structure 10 may be replaced with a dummy unit. That is, the lower molded structure 10 may include substrate portions 110 (e.g., only substrate portions 110) or some combination of substrate portions 110 and dummy units (not shown). The dummy unit may include, for example, a dummy die. The dummy unit may have a size, shape and placement substantially similar to a size, shape and placement of the substrate portions 110. In particular, the dummy unit may have a thickness in the z-direction substantially the same as a thickness of the substrate portions 110 so that a surface of the dummy unit opposite the interposer 20 may be substantially coplanar with a surface of the substrate portions 110 opposite the interposer 20. In at least one embodiment, the dummy unit may include a semiconductor such as silicon, an organic material, a metal material, etc.

In at least one embodiment, the substrate portions 110A, 110B and 110C may be separated from each other (in the x-direction) by a gap G1. The gap G1 may have a length (in the x-direction) in a range from 900 μm to 2000 μm. Other suitable lengths of the gap G1 are within the contemplated scope of discovery.

Each of the substrate portions 110A, 110B and 110C may include, for example, an organic substrate (e.g., a light organic substrate). Each of the substrate portions 110A, 110B and 110C may include a cored or coreless substrate. The substrate portions 110A, 110B and 110C may have different shapes, different routing functionalities or some combination of different shapes and routing functionalities. Thus, for example, the substrate portion 110A may have a first shape and a first routing functionality, and the substrate portion 110B may have a second shape different than the first shape and a second routing functionality different than the first routing functionality, and so on.

The lower molded structure 10 may also include a lower molding layer 27 (e.g., encapsulant) around the substrate portions 110A, 110B and 110C. The substrate portions 110A, 110B and 110C may be substantially encapsulated by the lower molding layer 27. In particular, the lower molding layer 27 may be located in the gap G1 between the substrate portions 110A, 110B and 110C. The lower molding layer 27 may bond to a sidewall of each of the substrate portions 110A, 110B and 110C.

The lower molded structure 10 may include a substantially planar lower surface S1. The substantially planar lower surface S1 may be constituted by a lower surface of the lower molding layer 27 and a lower surface of each of the substrate portions 110A, 110B and 110C.

In at least one embodiment, the lower molding layer 27 may be formed of a curable material that may cure to form a hard, solid structure. The lower molding layer 27 may include an encapsulant, dielectric material, etc. The lower molding layer 27 may include, for example, epoxy molding compound (EMC). In at least one embodiment, the lower molding layer 27 may include a polymeric material and in particular, an epoxy-based polymeric material. Other suitable molding materials may be used. In at least one embodiment, the lower molding layer 27 may include an added material (e.g., filler material) for improving a property of the lower molding layer 27 (e.g., thermal conductivity, CTE, etc.). The added material may include, for example, metal powder, metal oxide powder, etc. Other materials in the lower molding layer 27 are within the contemplated scope of the disclosure.

The interposer 20 may be connected to the lower molded structure 10 by a plurality of connectors such as microbumps 28. The connectors may additionally or alternatively include solder balls, C4 bumps, etc. In at least one embodiment, the connectors may include a ball grid array (BGA) including a plurality of solder balls with a ball-to-ball spacing (pitch) of 1.0 mm or 0.8 mm, or a micro BGA where the plurality of solder balls have a ball-to-ball spacing of about 0.4 mm or less. Other suitable connectors are within the contemplated scope of disclosure.

The microbumps 28 may each include a copper post and a solder bump on the copper post. The microbumps 28 may be bonded (e.g., by the solder bump) to metal contacts (e.g., bonding pads) on the substrate portions 110A, 110B and 110C. The lower molding layer 27 may be formed between the interposer 20 and around the microbumps 28. The lower molding layer 27 may bond to the interposer 20 and to the substrate portions 110A, 110B and 110C. The lower molding layer 27 may thereby fix the interposer 20 to the substrate portions 110A, 110B and 110C.

The lower molded structure 10 may optionally include an underfill layer (not shown) in the lower molding layer 27. The underfill layer may be formed (e.g., individually or connectively) under and around each of the substrate portions 110A, 110B and 110C. The underfill layer may also be formed around the microbumps 28. The underfill layer may thereby help to fix the interposer 20 to each of the substrate portions 110A, 110B and 110C. The underfill layer may be formed of an epoxy-based polymeric material.

As further illustrated in FIG. 1, the interposer 20 may include a back-side redistribution layer (RDL) interposer portion 21 (e.g., back side of interposer 20), a molded interposer portion 22 on the back-side RDL interposer portion 21, and a front-side RDL interposer portion 23 (e.g., front side of interposer 20) on the molded interposer portion 22. The upper molded structure 30 may be located on the front-side RDL interposer portion 23.

The back-side RDL interposer portion 21 is not limited to any particular materials or configuration. The back-side RDL interposer portion 21 may include, for example, organic material (e.g., dielectric polymer), inorganic material (e.g., silicon), glass substrate, etc. In at least one embodiment, the back-side RDL interposer portion 21 may include a plurality of polymer layers 12 and a plurality of redistribution layers 12a stacked alternately. The number of the polymer layers 12 and/or the number of redistribution layers 12a in the back-side RDL interposer portion 21 are not limited by the disclosure. The polymer layers 12 may also include the same of different materials. For example, as illustrated in FIG. 1, the two lowest polymer layers 12 (near the lower molded structure 10) and the uppermost polymer layer 12 (near the molded RDL portion 22) may include a first material, and the remaining polymer layers 12 may include a second material different than the first material. In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material.

In some embodiments, the redistribution layers 12a may include conductive materials. The conductive materials may include metal such as copper, aluminum, nickel, titanium, a combination thereof or other suitable metals. The redistribution layers 12a may include metallic connection structures, i.e., metallic structures that provide electrical connection between nodes in the structure. In at least one embodiment, the redistribution layers 12a may include a plurality of traces (lines) and a plurality of vias connecting the plurality traces to each other. The traces may be respectively located on the polymer layers 12 and may extend in the x-direction (first horizontal direction) and y-direction (second horizontal direction) on an upper surface of the polymer layers 12.

The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layer 12a may be in a range from 2 microns to 40 microns, such as from 4 microns to 10 microns, although lesser or greater thicknesses may also be used.

In at least one embodiment (e.g., where the interposer 20 is connected to the lower molded structure 10 by a micro BGA), one or more integrated passive devices (IPDs) (not shown) may be connected to the back-side RDL interposer portion 21 and located in the lower molding layer 27 of the lower molded structure 10. In at least one embodiment, the IPDs may be located between the back-side RDL interposer portion 21 and the substrate portions 110A, 110B and/or 110C. The IPDs may included bonding pads that are bonded to and electrically connected to the redistribution layers 12a. The IPDs may include one or more electronic components such as resistors, capacitors, inductors, coils, chokes, microstriplines, impedance matching elements, baluns, etc. The IPDs may be electrically coupled to the first semiconductor dies 141 through the back-side RDL interposer portion 21.

The molded interposer portion 22 may have a length in the x-direction that is substantially the same as a length in the x-direction of the back-side RDL interposer portion 21. The molded interposer portion 22 may have a width in the y-direction that is substantially the same as a width in the y-direction of the back-side RDL interposer portion 21. The molded interposer portion 22 may have a thickness in the z-direction less than a thickness of the back-side RDL interposer portion 21.

The molded interposer portion 22 may include a molding material layer 227 (e.g., encapsulation layer) formed on the back-side RDL interposer portion 21. In at least one embodiment, the molding material layer 227 may be formed of a curable material that may cure to form a hard, solid structure. The molding material layer 227 may include, for example, epoxy molding compound (EMC). In at least one embodiment, the molding material layer 227 may include a polymeric material and in particular, an epoxy-based polymeric material. Other suitable molding materials may be used. The molding material layer 227 may be different than or substantially the same as the lower molding layer 27 in the lower molded structure 10.

In at least one embodiment, the molding material layer 227 may have a CTE that is substantially similar to a CTE of the back-side RDL interposer portion 21. In at least one embodiment, the molding material layer 227 may include an added material (e.g., filler material) for improving a property of the molding material layer 227 (e.g., thermal conductivity, CTE, etc.). The added material may include, for example, metal powder, metal oxide powder, etc. Other materials in the molding material layer 227 are within the contemplated scope of the disclosure.

The molded interposer portion 22 may also include one or more local silicon interconnect (LSI) dies 200 (e.g., silicon bridge). The molding material layer 227 may be formed around the LSI die 200 in the x-direction and y-direction. In at least one embodiment, the LSI die 200 may be substantially embedded in the molding material layer 227.

The LSI die 200 may be inverted and mounted on the front-side RDL interposer portion 23. The LSI die 200 may be bonded to the front-side RDL interposer portion 23, for example, by one or more connectors such as microbumps 228. The microbumps 228 may be similar to the microbumps 28 described above. An LSI underfill layer 229 may optionally be formed around the microbumps 228 and between the LSI die 200 and the front-side RDL interposer portion 23. The LSI die 200 may alternatively or additionally be bonded to the front-side RDL interposer portion 23, for example, by a “hybrid” bond that includes an oxide-oxide bond and a metal-metal bond. Other connectors and connections between the LSI die 200 and the front-side RDL interposer portion 23 are within the contemplated scope of disclosure.

The LSI die 200 may include an LSI RDL section 204 and one or more through silicon vias (TSVs) 202 electrically coupling the redistribution layers 12a in the back-side RDL interposer portion 21 to the LSI RDL section 204. The TSVs 202 may include, for example, one or more layers and may include metals, metal alloys, and/or other metal-containing compounds (e.g., Cu, Al, Mo, Co, Ru, W, TiN, TaN, WN, etc.).

The LSI RDL section 204 may include, for example, one or more redistribution layers (e.g., interconnect structures) such as metal traces and metal vias (not shown) for interconnecting the first semiconductor dies 141 in the upper molded structure 30. In at least one embodiment, the redistribution layers may provide a high routing density die-to-die interconnect through multiple layers of sub-micron metal (e.g., copper) lines. The redistribution layers may allow the LSI die 200 to accommodate a plurality of different connection architectures (e.g., SoC to SoC, SoC to chiplet, SoC to HBM, etc.). The redistribution layers may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The molded interposer portion 22 may also integrate one or more additional elements 240 bonded to the front-side RDL interposer portion 23. The additional elements 240 may be located in the molding material layer 227 underneath one or more of the first semiconductor dies 141. The additional elements 240 may include, for example, one or more integrated voltage regulators (iVRs) for regulating a voltage in the package structure 100. The additional elements 240 may include, for example, one or more stand-alone IPDs to support signal communication with the first semiconductor dies 141.

The additional elements 240 may be inverted and mounted on the front-side RDL interposer portion 23. The additional elements 240 may be bonded to the front-side RDL interposer portion 23, for example, by one or more connectors such as microbumps 328. The microbumps 328 may be similar to the microbumps 28 and microbumps 228 described above. An underfill layer 329 may optionally be formed around the microbumps 328 and between the additional elements 240 and the front-side RDL interposer portion 23. The optional underfill layer 329 may be formed of an epoxy-based polymeric material. The additional elements 240 may alternatively or additionally be bonded to the front-side RDL interposer portion 23, for example, by a “hybrid” bond that includes an oxide-oxide bond and a metal-metal bond. Other connectors and connections between the additional elements 240 and the front-side RDL interposer portion 23 are within the contemplated scope of disclosure.

The molded interposer portion 22 may also include one or more through vias (TVs) 206 in the molding material layer 227. The TVs 206 may connect the front-side RDL interposer portion 23 to the redistribution layers 12a in the back-side RDL interposer portion 21. The TVs 206 may include, for example, one or more layers and may include metals, metal alloys, and/or other metal-containing compounds (e.g., Cu, Al, Mo, Co, Ru, W, TiN, TaN, WN, etc.).

The front-side RDL interposer portion 23 may have a structure similar to the structure of the back-side RDL interposer portion 21. In particular, the front-side RDL interposer portion 23 may include the plurality of polymer layers 12 and the plurality of redistribution layers 12a stacked alternately. The number of the polymer layers 12 and/or the number of redistribution layers 12a in the front-side RDL interposer portion 23 are not limited by the disclosure. In at least one embodiment, the front-side RDL interposer portion 23 may include fewer polymer layers 12 than the back-side RDL interposer portion 21. The polymer layers 12 may include, for example, the same material as the uppermost polymer layer 12 and two lowest polymer layers 12 in the back-side RDL interposer portion 21.

The redistribution layers 12a in the front-side RDL interposer portion 23 may be substantially the same as the redistribution layers 12a in the back-side RDL interposer portion 21. In particular, in both the front-side RDL interposer portion 23 and back-side RDL interposer portion 21, the redistribution layers 12a may include a wide pitch and may be connected to each other by the TVs 206 for efficient signal and power delivery. With such a configuration, the interposer 20 may provide low loss of high frequency signal in high-speed transmission.

The upper molded structure 30 may have a length in the x-direction that is substantially the same as a length in the x-direction of the interposer 20. The upper molded structure 30 may have a width in the y-direction that is substantially the same as a width in the y-direction of the interposer 20. In at least one embodiment, the front-side RDL interposer portion 23 may be omitted and the upper molded structure 30 may be attached to the molded interposer portion 22.

The upper molded structure 30 may include the first semiconductor dies 141 attached to an upper surface of the front-side RDL interposer portion 23. The first semiconductor dies 141 may be separated by a die-to-die gap G_{D2D}. The die-to-die gap G_{D2D} may extend longitudinally in the y-direction and have a width in the x-direction in a range from 1 μm to 1000 μm (e.g., about 100 μm). Generally, a thickness in the z-direction of each of the first semiconductor dies 141 may be substantially the same. Thus, the upper surfaces of each of the first semiconductor dies 141 may be substantially coplanar (e.g., formed in the same x-y plane), and referred to collectively as the semiconductor die upper surface 140a.

The upper molded structure 30 may include a substantially planar upper surface S2. The substantially planar upper surface S2 may be constituted by an upper surface of the upper molding layer 127 and the semiconductor die upper surface 140a.

The first semiconductor dies 141 may be attached the front-side RDL interposer portion 23, for example, by flip-chip bonding using a plurality of connectors such as microbumps 128. The connectors may additionally or alternatively include solder balls, C4 bumps, etc. The microbumps 128 may be similar to the microbumps 28, microbumps 228 and microbumps 328 described above.

In at least one embodiment, the microbumps 128 may each include a copper post and a solder bump on the copper post. The microbumps 128 may be bonded (e.g., by the solder bump) to the redistribution layers 12a in the front-side RDL interposer portion 23. The first semiconductor dies 141 may be electrically coupled to the LSI die 200 through the microbumps 128, the redistribution layers 12a in the front-side RDL interposer portion 23 and the microbumps 228 in the molded interposer portion 22. The first semiconductor dies 141 may alternatively or additionally be attached the front-side RDL interposer portion 23, for example, by hybrid bonding, direct bonding or fusion bonding (e.g., metal-to-metal bonding).

A package underfill layer 129 may optionally be formed (e.g., individually or connectively) under and around each of the first semiconductor dies 141. The package underfill layer 129 may also be formed around the microbumps 128. The package underfill layer 129 may thereby fix each of the first semiconductor dies 141 to the front-side RDL interposer portion 23. The package underfill layer 129 may be formed of an epoxy-based polymeric material.

Each of the first semiconductor dies 141 may include, for example, a singular semiconductor die, a system on chip (SOC) die, or a system on integrated chips (SoIC) die, and may be implemented by stacked device technology. For example, chip-on-wafer-on-substrate (CoWoS) technology or integrated fan-out on substrate (INFO-oS) technology. In particular, each of the first semiconductor dies 141 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor dies 141 may include a combination of one or more primary dies (e.g., SOC dies) and one or more ancillary dies (e.g, memory/SOC dies, HBM dies, etc.).

The upper molded structure 30 may also include an upper molding layer 127 formed around the first semiconductor dies 141. The upper molding layer 127 may have an outer sidewall that is substantially aligned with an outer sidewall of the interposer 20 and an outer sidewall of the lower molded structure 10. The upper molding layer 127 may also have an upper surface that is substantially uniform (e.g., flat) and substantially coplanar with the upper surface 140a of the first semiconductor dies 141. The upper molding layer 127 may be formed on sidewalls (inner sidewall and outer sidewall) of each of the first semiconductor dies 141. The upper molding layer 127 may be bonded to the sidewalls of each of the first semiconductor dies 141.

The upper molding layer 127 may also be formed on and around the package underfill layer 129. The upper molding layer 127 may also be formed in the die-to-die gap G_{D2D} between the first semiconductor dies 141. In at least one embodiment, the upper molding layer 127 may be formed on the package underfill layer 129 in the die-to-die gap G_{D2D}. The upper molding layer 127 may be bonded to the front-side RDL interposer portion 23 and the package underfill layer 129.

In at least one embodiment, the upper molding layer 127 may include a material that is substantially similar to the package underfill layer 129, substantially similar to the molding material layer 227 in the molded interposer portion 22, and/or substantially similar to the lower molding layer 27 in the lower molded structure 10. In particular, the upper molding layer 127 may be formed of a curable material that may cure to form a hard, solid structure. The upper molding layer 127 may include, for example, epoxy molding compound (EMC). In at least one embodiment, the upper molding layer 127 may include a polymeric material and in particular, an epoxy-based polymeric material. Other suitable molding materials may be used.

In at least one embodiment, the upper molding layer 127 may have a CTE that is substantially similar to a CTE of the front-side RDL interposer portion 23, a CTE of the molded interposer portion 22 and/or a CTE of the back-side RDL interposer portion 21. In at least one embodiment, the upper molding layer 127 may include an added material (e.g., filler material) for improving a property of the upper molding layer 127 (e.g., thermal conductivity, CTE, etc.). The added material may include, for example, metal powder, metal oxide powder, etc. Other materials in the upper molding layer 127 are within the contemplated scope of the disclosure.

The components 41 may include, for example, one or more different components such as logic components, memory components, passive components, etc. In at least one embodiment, the components 41 may include semiconductor dies such as the first semiconductor dies 141 described above. In at least one embodiment, the components 41 may include voltage regulator modules (VRMs) that may regulate a voltage in the package structure 100. In particular, the VRMs may include a converter (e.g., DC-to-DC converter) that steps down voltage (e.g., while stepping up current) from a power supply unit into a lower operating voltage of an integrated circuit (e.g., in the first semiconductor dies 141).

The connectors 42 may include, for example, solder balls, bumps, pin connectors, socket connectors, etc. In at least one embodiment, a height of the connectors 42 in the z-direction may be substantially the same as a height of the components 41. In at least one embodiment, the height of the connectors 42 in the z-direction may be greater than or less than the height of the components 41.

In at least one embodiment, any one or more of the components 41 and connectors 42 in FIG. 1 may include a semiconductor component such as a logic die, memory die, input/output (I/O) dies, a VRM, a capacitor, etc. In at least one embodiment, any one or more of the components 41 and connectors 42 in FIG. 1 may include a connector such as socket, connector with pins, solder balls, BGA balls, etc. In at least one embodiment, any one or more of the components 41 and connectors 42 in FIG. 1 may include a suitable circuit carrier/motherboard, such as printed circuit board (PCB), etc. In at least one embodiment, any one or more of the components 41 and connectors 42 in FIG. 1 may include a combination of one or more of the above embodiments if needed and possible based the layout.

The components 41 and connectors 42 may be separated by a gap G40 in a range from 100 μm to 2000 μm (e.g., about 500 μm). The components 41 and connectors 42 may be bonded, for example, to the substantially planar lower surface S1 of the lower molded structure 10. In particular, the components 41 and connectors 42 may be bonded to and electrically coupled to at least one of the substrate portions 110A, 110B and 110C.

The components 41 and connectors 42 may be attached to the substantially planar lower surface S1 of the lower molded structure 10 by a plurality of connectors such as microbumps 428. The microbumps 428 may be substantially similar to the microbumps 28, microbumps 228, microbumps 328 and microbumps 128 described above. The connectors may additionally or alternatively include solder balls, C4 bumps, etc. In at least one embodiment, the connectors may include a BGA including a plurality of solder balls with a ball-to-ball spacing of 1.0 mm or 0.8 mm, or a micro BGA where the plurality of solder balls have a ball-to-ball spacing of about 0.4 mm or less. Other suitable connectors are within the contemplated scope of disclosure.

The package structure 100 may optionally include an underfill layer (not shown) around the microbumps 428. The underfill layer may be formed (e.g., individually or connectively) under and around each of the components 41 and connectors 42. The underfill layer may thereby help to fix the components 41 and connectors 42 to the substantially planar lower surface S1 of the lower molded structure 10. In particular, the underfill layer may thereby help to fix the components 41 and connectors 42 to each of the substrate portions 110A, 110B and 110C. The underfill layer may also be formed of an epoxy-based polymeric material.

The package structure 100 may provide a chip-on-wafer-on-substrate plus LSI die technology (CoWoS L+) for an SoW application. The package structure 100 may overcome process and reliability concerns in SoW, by including 1) the interposer 20 having multiple RDL layers for chip interconnection and a package stress buffer, and 2) a discrete substrate such as a light organic substrate (e.g., substrate portions 110) bonded to the interposer 20 to compensate for possible wafer CTE mismatch and reduce wafer warpage. The package structure 100 may also include the upper molded structure 30 (e.g., molding material at a front-side of the interposer 20) and the lower molded structure 10 (e.g., including the substrate portions 110 in lower molding layer 27) at a back-side of the interposer 20.

The package structure 100 may have several advantages. The package stress in silicon may be buffered by including multiple RDL layers in the interposer 20. Wafer warpage may be improved by adding the bonded substrate portions 110. The package structure 100 (e.g., final structure) may also be compatible with current processes (e.g., SoW technology would like to adopt local silicon interconnect (LSI) bridges to connect SoC/high-bandwidth memory (HBM)/Chiplets).

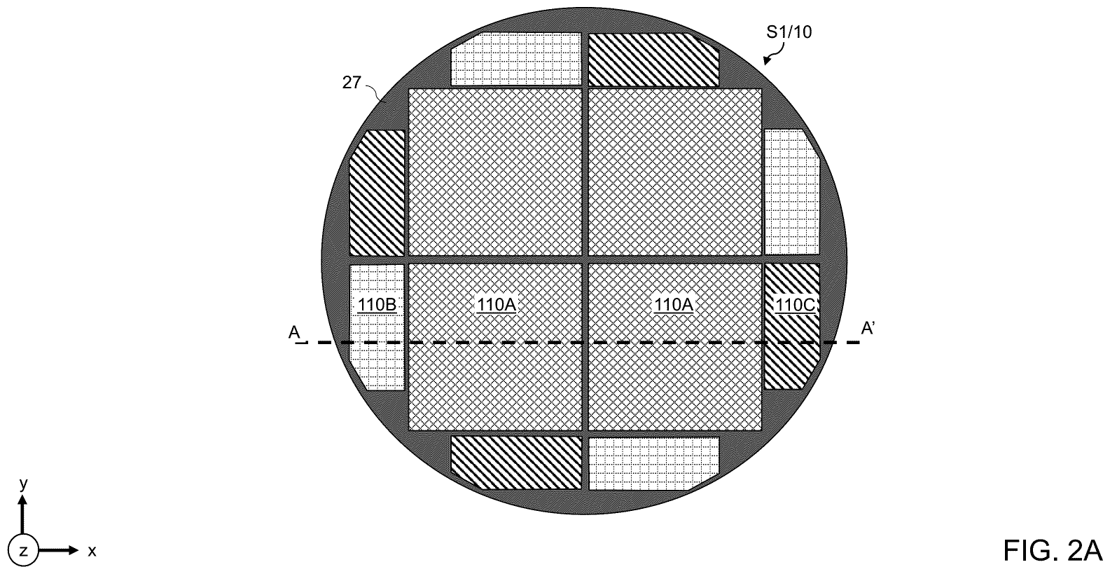

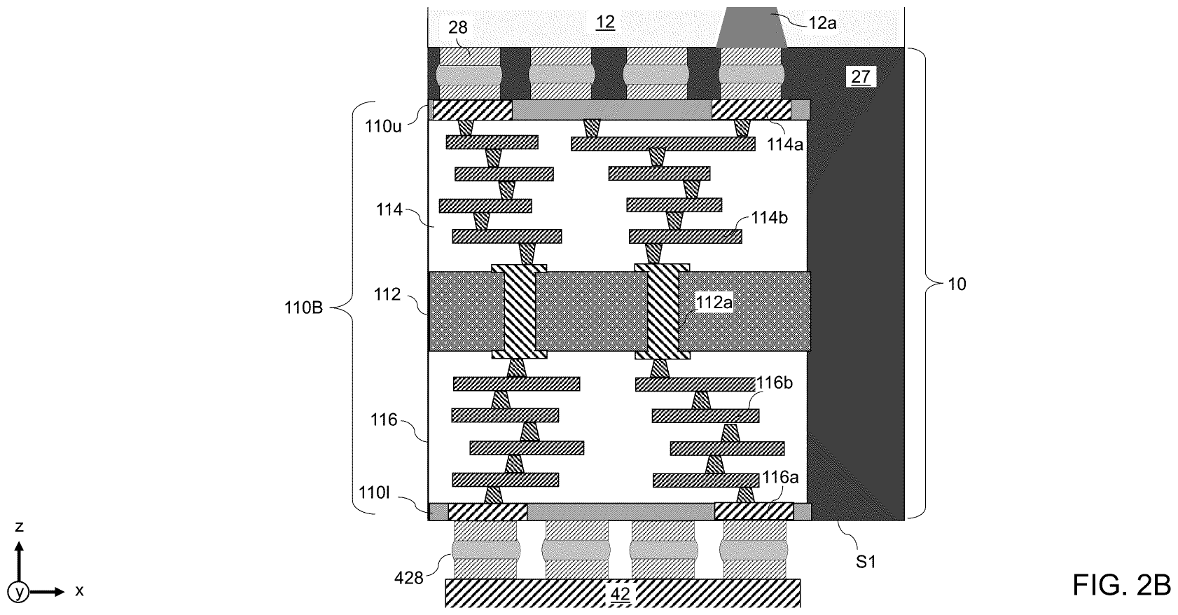

FIG. 2A is a bottom-up view of the substantially planar lower surface S1 of the lower molded structure 10, according to one or more embodiments. The vertical cross-sectional view in FIG. 1 is along the line A-A′ in FIG. 2A. The components 41, connectors 42 and microbumps 428 have been omitted from FIG. 2A for ease of explanation.

As illustrated in FIG. 2A, the package structure 100 may include one or more substrate portions 110A, 110B and 110C in the lower molding layer 27. The substrate portions 110A, 110B and 110C may be surrounded in the x-direction and y-direction by the lower molding layer 27. The substrate portions 110A, 110B and 110C may be cut (e.g., by dicing) and arranged so as to account for most of the substantially planar lower surface S1. In at least one embodiment, at least 70 percent of the substantially planar lower surface S1 may be constituted by the substrate portions 110A, 110B and 110C. That is, less than 30 percent of the substantially planar lower surface S1 may be constituted by the lower molding layer 27.

FIG. 2B is a detailed vertical cross-sectional view of a portion of the lower molded structure 10 including the substrate portion 110B, according to one or more embodiments. The substrate portions 110A and 110C may have a structure substantially similar to the structure of the substrate portion 110B in FIG. 2B.

As illustrated in FIG. 2B, the substrate portion 110B may include a core 112, a substrate upper dielectric layer 114 formed on the core 112 (e.g., an upper side of the substrate portion 110B), and a substrate lower dielectric layer 116 formed on the core 112 (e.g., a lower side of the substrate portion 110B). In particular, the substrate portion 110B may include a build-up film substrate such as an Ajinomoto build-up film (ABF) substrate. That is, in at least one embodiment, each of the substrate upper dielectric layer 114 and the substrate lower dielectric layer 116 may be described as an ABF layer.

The core 112 may help to provide rigidity to the substrate portion 110B. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the substrate upper dielectric layer 114 and the substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The substrate upper dielectric layer 114 may be formed on an upper surface of the core 112. The substrate upper dielectric layer 114 may include a plurality of layers and, in particular, may include a build-up film (e.g., ABF). The substrate upper dielectric layer 114 may also include an organic material such as a polymer material. In particular, the substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

One or more substrate upper bonding pads 114a may be formed on the substrate upper dielectric layer 114. The substrate upper dielectric layer 114 may include one or more metal interconnect structures 114b (conductive layers). The metal interconnect structures 114b may be connected to the substrate upper bonding pads 114a and the through vias 112a in the core 112. The metal interconnect structures 114b may include metal layers (e.g., copper traces) and metal vias connecting the metal layers. As illustrated in FIG. 2B, the substrate upper bonding pads 114a may be bonded by a microbump 28 to a redistribution layer 12a in a dielectric layer 12 of the back-side RDL interposer portion 21. The substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A substrate upper passivation layer 110u may be formed on a surface of the substrate upper dielectric layer 114. The substrate upper passivation layer 110u may partially cover the substrate upper bonding pads 114a. The upper passivation layer 110u may include silicon oxide, silicon nitride, low-k dielectric materials such as carbon-doped oxides, extremely low-k dielectric materials such as porous carbon doped silicon dioxide, a combination thereof or other suitable material.

The substrate lower dielectric layer 116 may be formed on a surface of the core 112. The substrate lower dielectric layer 116 may include a plurality of layers and, in particular, may include a build-up film (e.g., ABF). The substrate lower dielectric layer 116 may also include an organic material such as a polymer material. In particular, the substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

One or more substrate lower bonding pads 116a may be formed on a surface of the substrate lower dielectric layer 116. The substrate lower dielectric layer 116 may include one or more metal interconnect structures 116b (conductive layers). The metal interconnect structures 116b may be connected to the substrate lower bonding pads 116a and the through vias 112a in the core 112. The metal interconnect structures 116b may include metal layers (e.g., copper traces) and metal vias connecting the metal layers. As illustrated in FIG. 2B, the substrate lower bonding pads 116a may be bonded by a microbump 428 to the connector 42 or a component 41 (not shown). The substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A substrate lower passivation layer 110b may be formed on a surface of the substrate lower dielectric layer 116. The substrate lower passivation layer 110b may partially cover the substrate lower bonding pads 116a. The substantially planar lower surface S1 include a surface of the substrate lower passivation layer 1101. The substrate lower passivation layer 1101 may include silicon oxide, silicon nitride, low-k dielectric materials such as carbon-doped oxides, extremely low-k dielectric materials such as porous carbon doped silicon dioxide, a combination thereof or other suitable material.

It should be noted that the substrate portions 110 may have a structure that is different than the structure illustrated in FIG. 2B. In particular, a structure of one or more of the substrate portions 110 may include a core with a dual-side RDL (e.g., a core with substrate upper dielectric layer 114 and substrate lower dielectric layer 116 as illustrated in FIG. 2B). In a first alternative (option A), a structure of one or more of the substrate portions 110 may include a core with a single-side RDL (e.g., a core with the substrate upper dielectric layer 114 between the interposer 20 and the core). In a second alternative (option B), a structure of one or more of the substrate portions 110 may include a core with a single-side RDL (e.g., a core with the substrate lower dielectric layer 116 between the components 41/connectors 42 and the core). In a third alternative, a structure of one or more of the substrate portions 110 may include a coreless structure including an RDL (of multiple build-up layers).

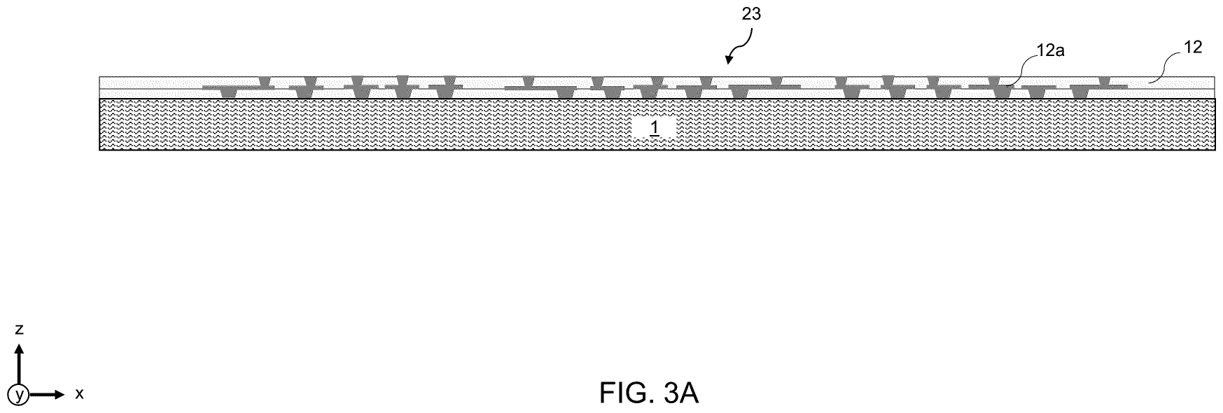

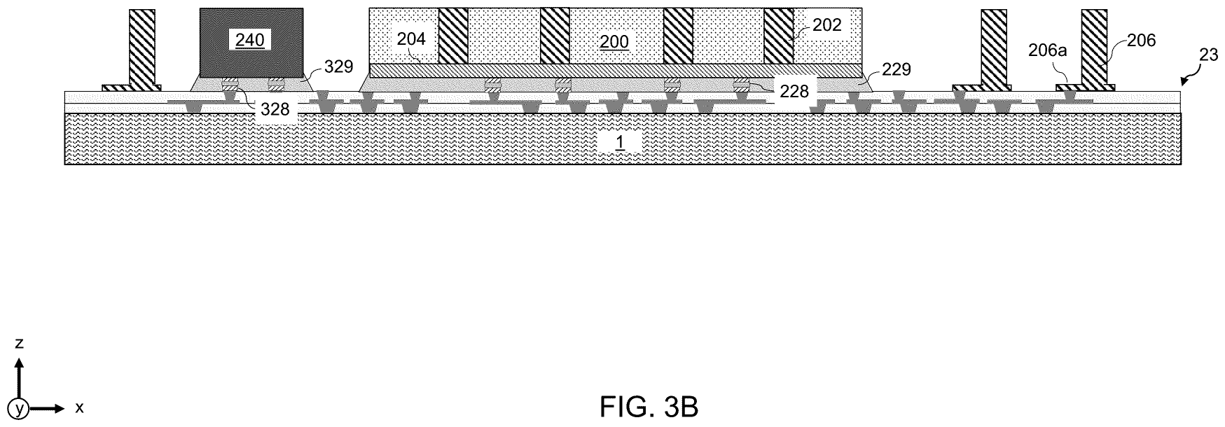

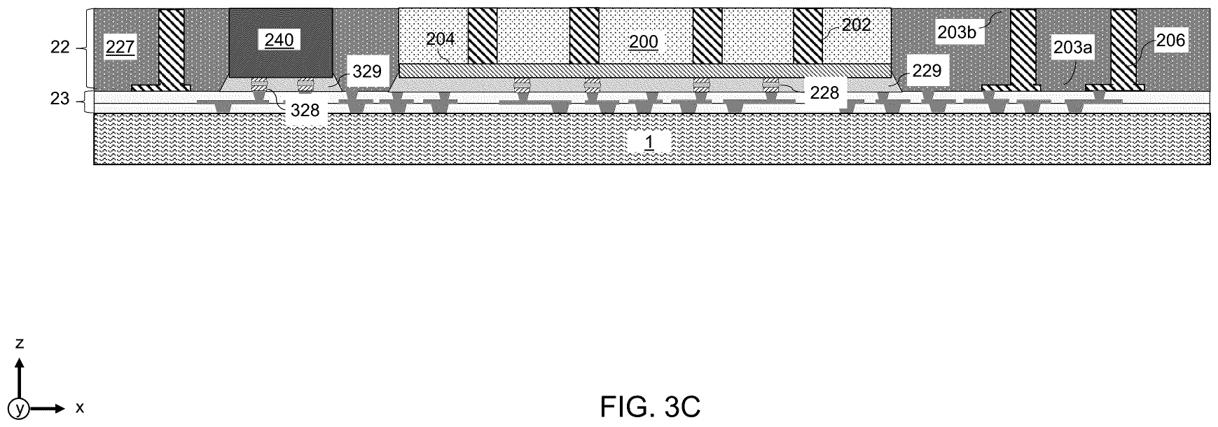

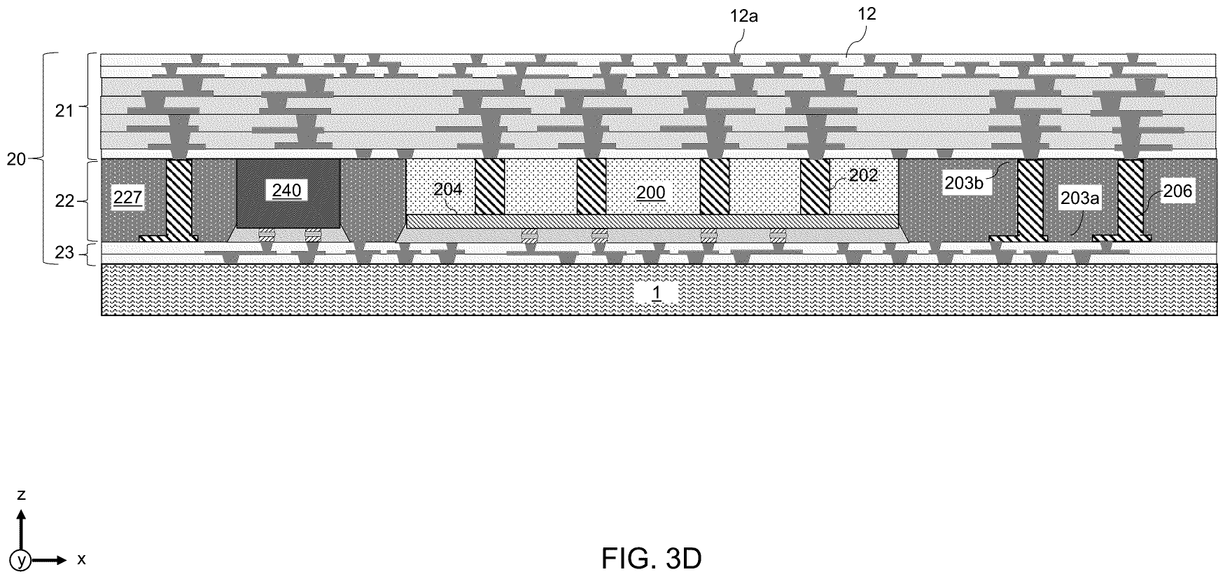

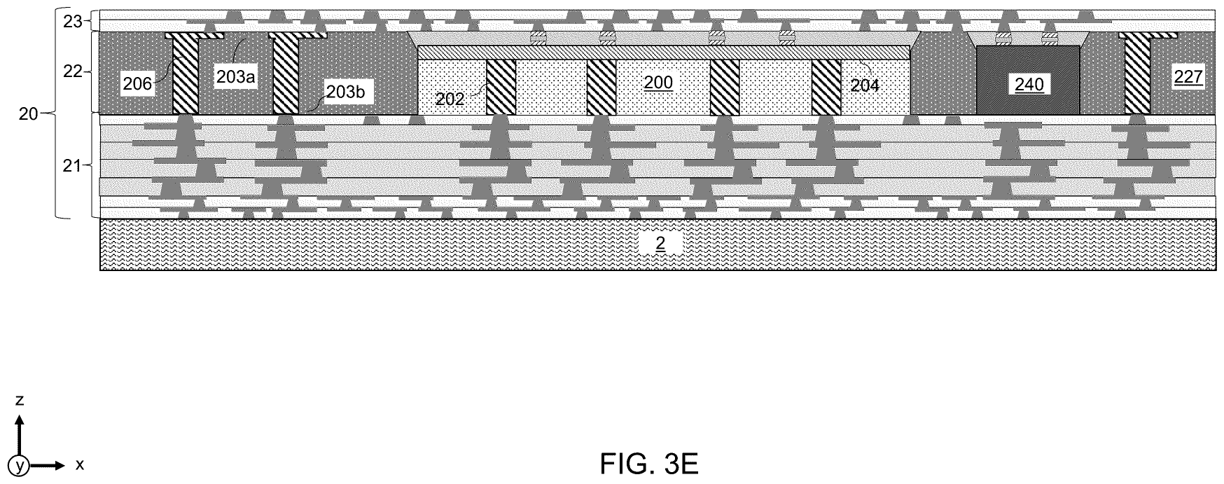

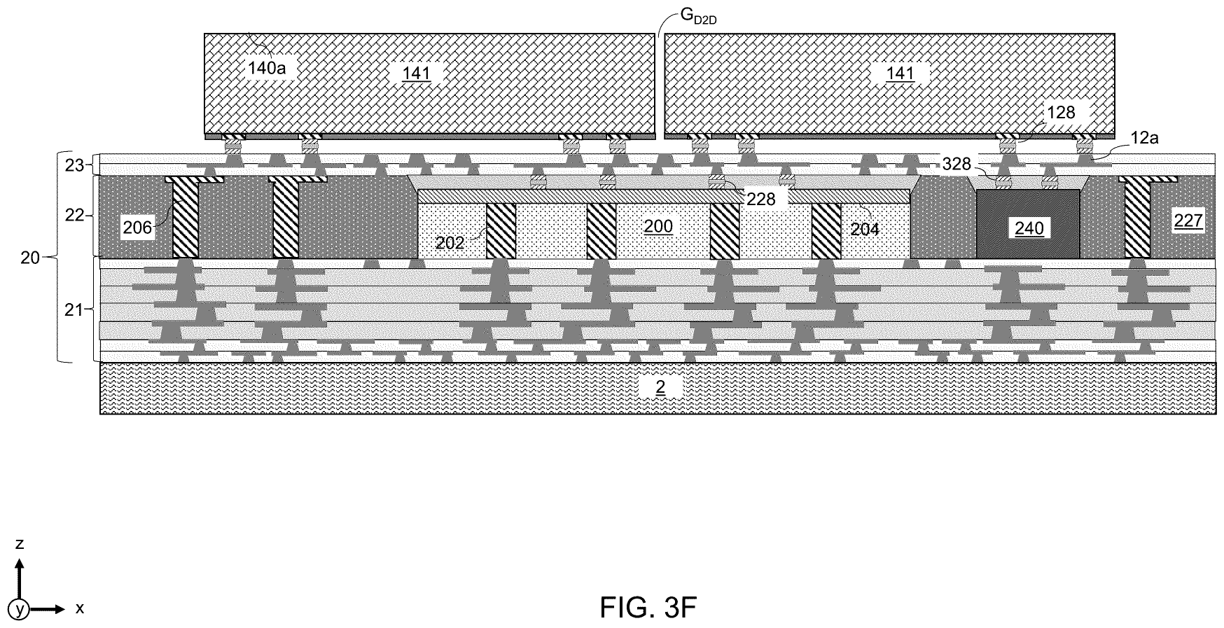

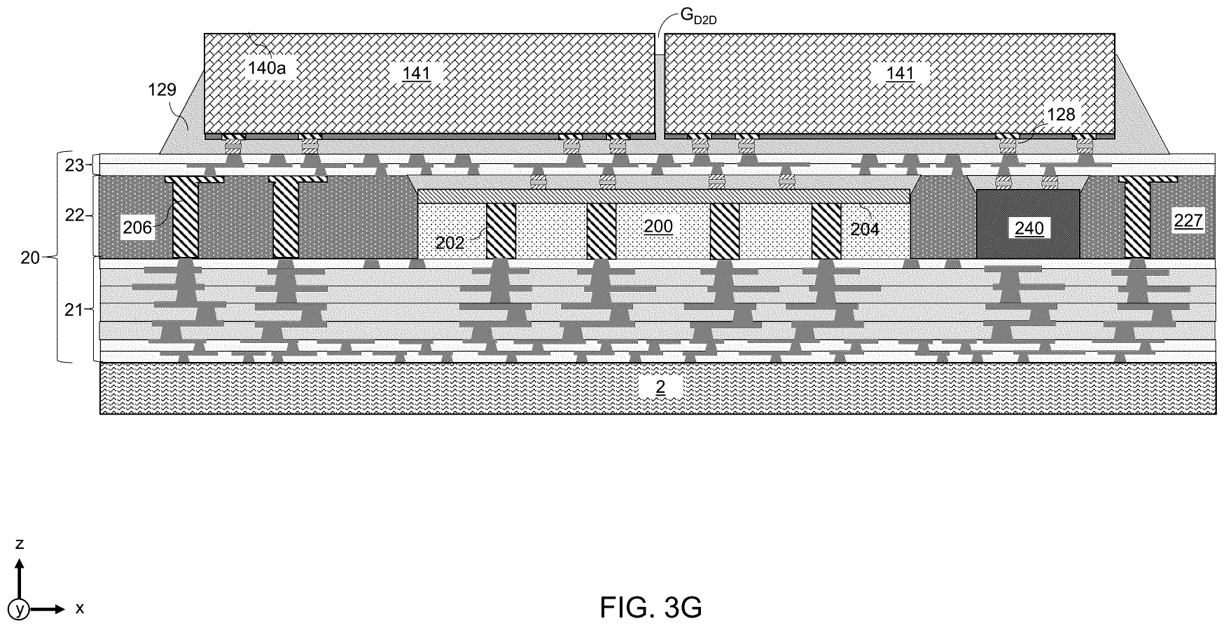

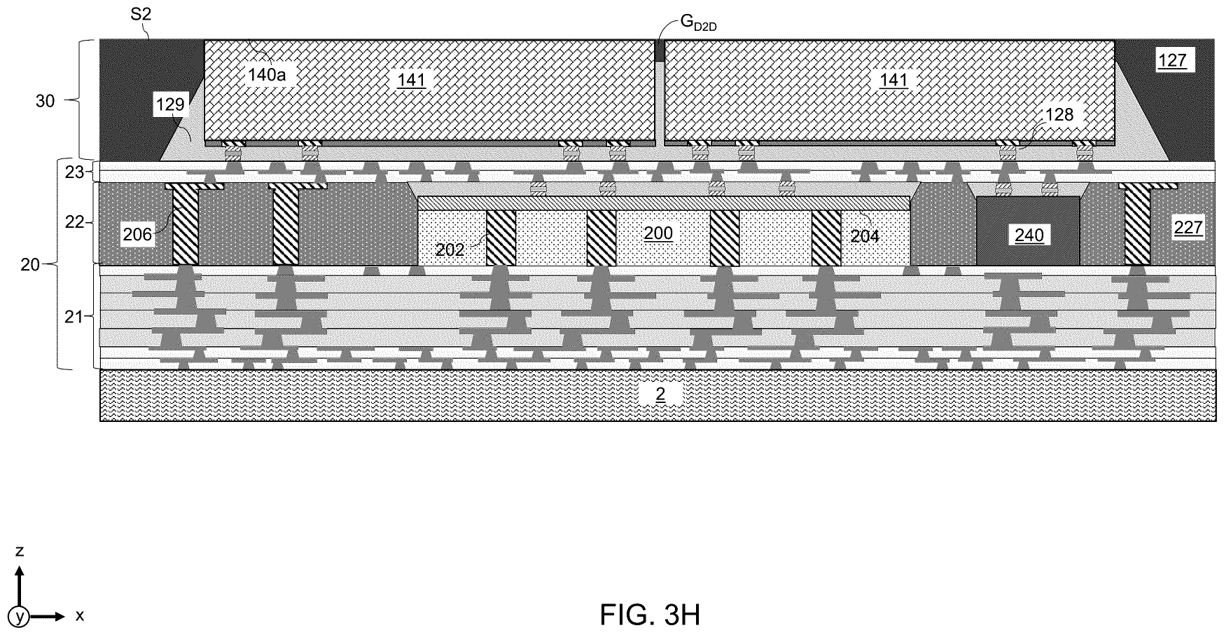

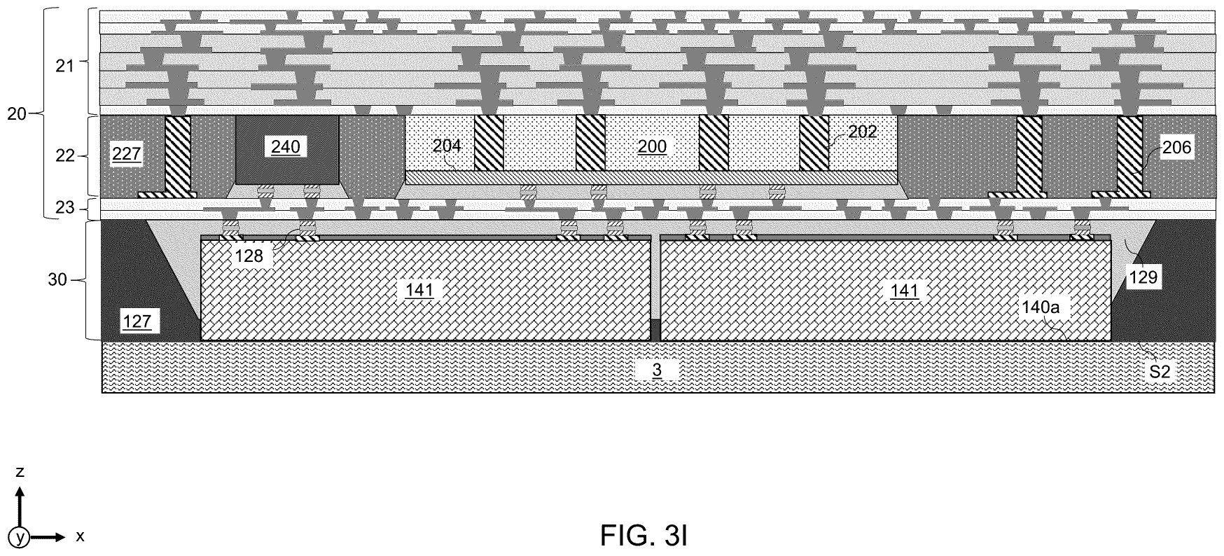

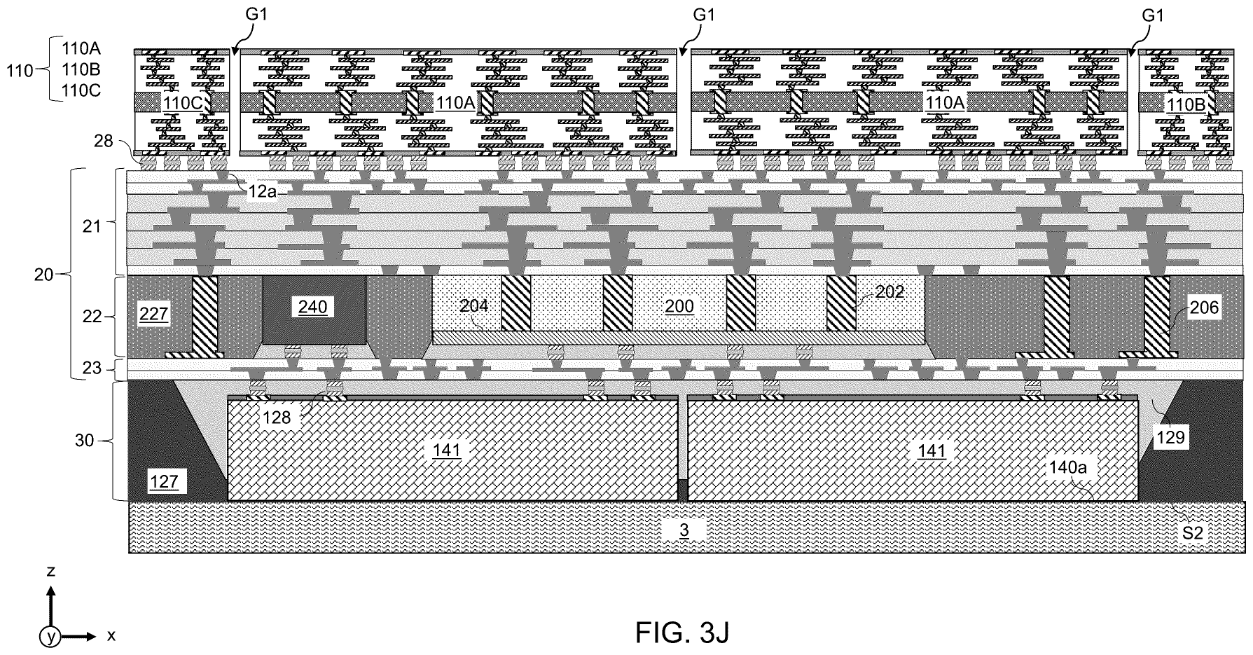

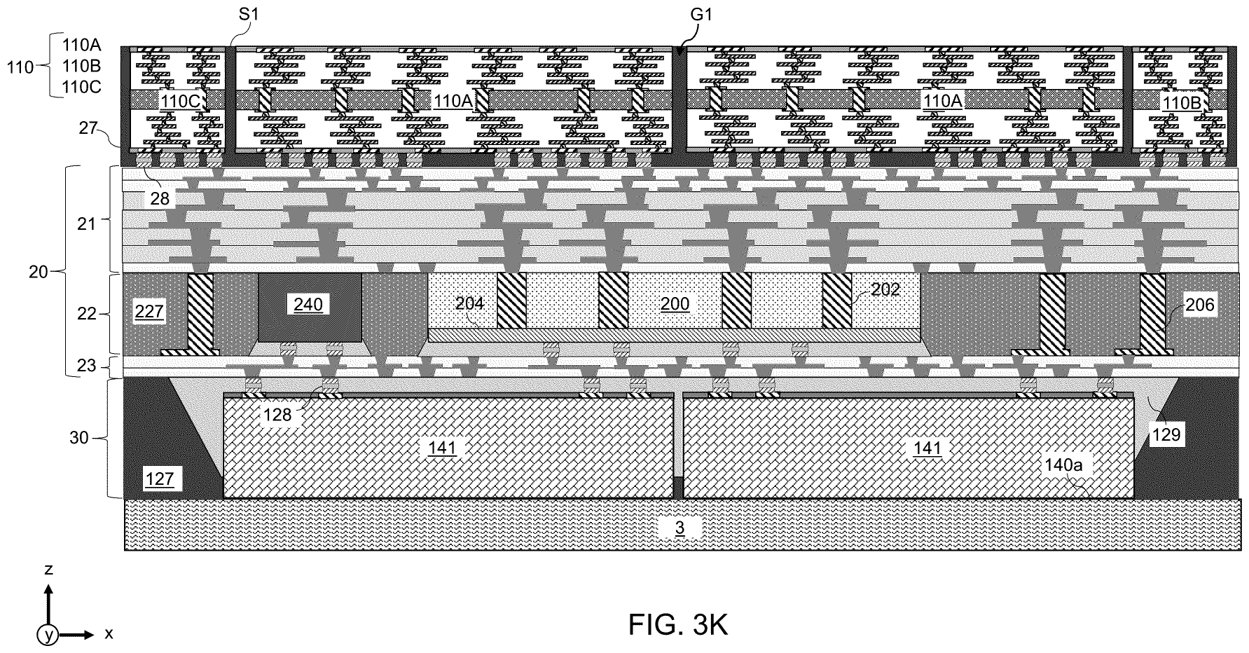

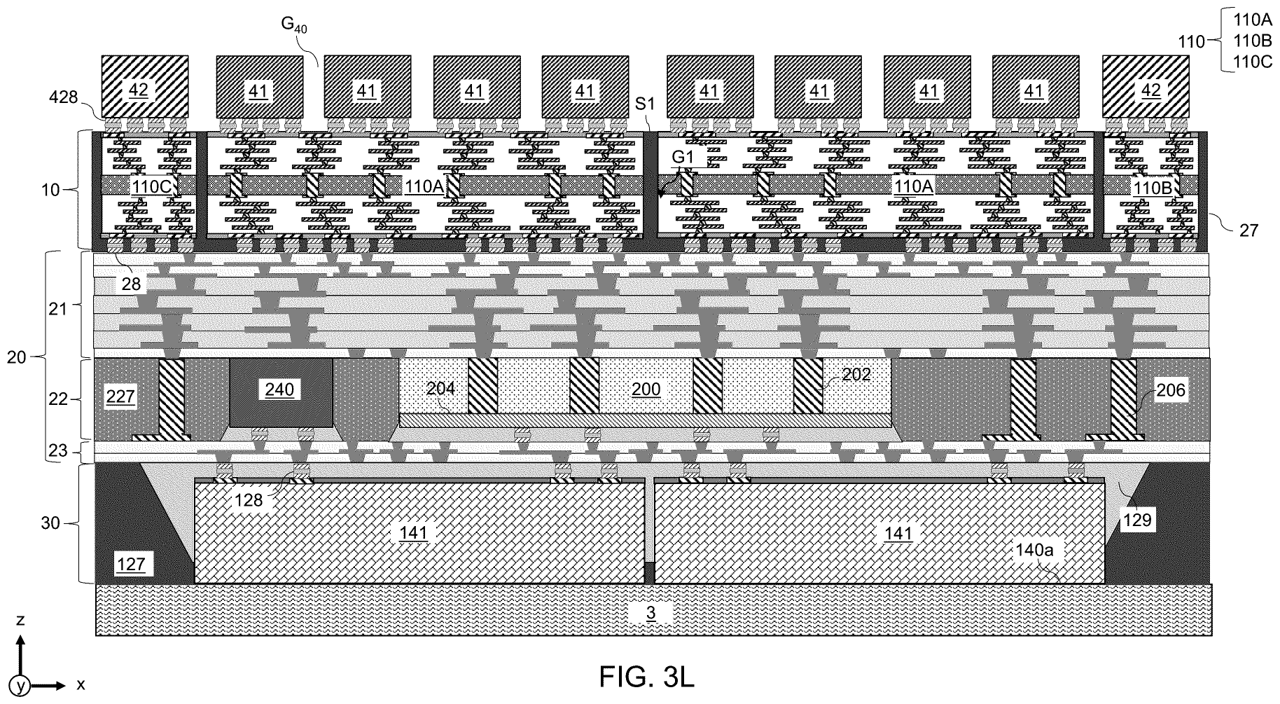

FIGS. 3A-3L illustrate various intermediate structures in a method of forming the package structure 100 according to one or more embodiments. FIG. 3A is a vertical cross-sectional view of an intermediate structure including the front-side RDL interposer portion 23 formed on a first carrier substrate 1 (e.g., carrier wafer) according to one or more embodiments.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used.

An adhesive layer (not shown) may be applied to the top surface of the first carrier substrate 1. In one embodiment, the first carrier substrate 1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

The plurality of dielectric layers 12 and plurality of redistribution layers 12a may be alternately formed on the first carrier substrate 1 (e.g., on the adhesive layer on the first carrier substrate 1). It should be noted that although FIG. 3A illustrates two dielectric layers 12 and two redistribution layers 12a, more or fewer dielectric layers 12 and redistribution layers 12a are within the contemplated scope of disclosure.

Each dielectric layer 12 may each be formed, for example, by depositing (e.g., by CVD, PVD or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The redistribution layer 12a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

After the uppermost redistribution layer 12a is deposited, an upper surface of the front-side RDL interposer portion 23 may then be planarized (e.g., by wet etching, drying etching, chemical mechanical polishing (CMP), etc.). The planarization may be performed to make an upper surface of the uppermost redistribution layer 12a substantially coplanar with an upper surface of the uppermost dielectric layer 12.

FIG. 3B is a vertical cross-sectional view of an intermediate structure including the LSI die 200 according to one or more embodiments. A metal seed layer 206a may be formed on the front-side RDL interposer portion 23 by a deposition and photolithographic process. In particular, the metal seed layer 206a may be deposited (e.g., by CVD, PVD or other suitable deposition process) on the uppermost dielectric layer 12. The metal seed layer 206a may then be patterned by a photolithographic process. The photolithographic process may include forming a patterned photoresist mask (not shown) on the metal layer, and etching (e.g., wet etching, dry etching, etc.) the exposed upper surface of the metal layer through openings in the photoresist mask. The photoresist mask may be subsequently removed by ashing, dissolving the photoresist mask or by consuming the photoresist mask during the etch process.

The through vias (TVs) 206 may then be formed on the metal seed layers 206a in one or more electroplating processes. In one or more embodiments, a metal material may be electroplated on the metal seed layer 206a to form the through vias 206. The metal material for electroplating may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The LSI die 200 may then be placed on the front-side RDL interposer portion 23, for example, by using an electromechanical pick-and-place (PNP) machine. The microbumps 228 may be formed on the LSI die 200. Using a flip-chip process, the bumped LSI die 200 may be connected to the front-side RDL interposer portion 23.

The microbumps 228 may include a copper pillar with a solder cap, based on a tin/silver alloy. The microbumps 228 may be formed, for example, by depositing an under-bump metallurgy (UBM) on the bottom surface of the LSI die 200. Then, a photoresist may be applied on the UBM. The desired bump size may be patterned and etched, forming a small gap in the resist. A copper layer may then be plated over the surface, forming a pillar in the gap. In some cases, this material is reflowed or heated, forming the microbump 228. The underfill layer 229 may then be formed under the LSI die 200 and around the microbumps 228. The underfill layer 229 may then be cured in an oven.

The additional elements 240 may be attached to the front-side RDL interposer portion 23 by a similar process. It should be noted that the chronological order of forming the through vias 206 and attaching the additional elements 240 and the LSI die 200 is not necessarily limited to any particular order.

Alternatively or additionally, the LSI die 200 may be bonded to the front-side RDLinterposer portion 23 by a hybrid bonding process (e.g., metal-metal bonding, oxide-oxide bonding). In particular, lower contacts (not shown) of the LSI die 200 may be directly bonded to the uppermost redistribution layer 12a in the front-side RDL interposer portion 23. The LSI die 200 may thereby be electrically connected to the redistribution layer 12a of the front-side RDL interposer portion 23.

FIG. 3C is a vertical cross-sectional view of an intermediate structure including the molding material layer 227 according to one or more embodiments. The molding material layer 227 (e.g., encapsulant layer) may be formed by a sequence of an over-molding process and a planarization process. In particular, the molding material layer 227 may include an epoxy polymer material (e.g., an epoxy molding compound (EMC). The molding material layer 227 may be formed on the front-side RDL interposer portion 23 and fill in the gaps between the LSI die 200, the through vias 206 and the additional elements 240. The molding material layer 227 may encapsulate (e.g., in the x-direction and y-direction) the LSI die 200, through vias 206 and additional elements 240. The molding material layer 227 may be formed, for example, by a deposition process such as CVD, PECVD, PVD, spin coating, lamination or other suitable deposition technique.

The molding material layer 227 may be deposited so as to completely cover the LSI die 200, through vias 206 and additional elements 240. After the molding material layer 227 has cured, a planarization process (e.g., chemical mechanical planarization/polishing (CMP)) may then be used to make an upper surface of the molding material layer 227 coplanar with an upper surface of the LSI die 200, an upper surface of the through vias 206 and an upper surface of the additional elements 240. In particular, the planarization process may be performed on the upper surface of the molding material layer 227 until an upper surface of the LSI die 200, an upper surface of the through vias 206 and an upper surface of the additional elements 240 are exposed. The planarization process may include, for example, a mechanical grinding process and/or a CMP process. The planarization process may complete the formation of the molded interposer portion 22.

FIG. 3D is a vertical cross-sectional view of an intermediate structure including the back-side RDL interposer portion 21 on the molded interposer portion 22 according to one or more embodiments. The back-side RDL interposer portion 21 may be formed using a process that is substantially the same as the process for forming the front-side RDL interposer portion 23 described above. That is, the plurality of dielectric layers 12 and plurality of redistribution layers 12a may be alternately formed on the planarized surface of the molded interposer portion 22. It should be noted that although FIG. 3D illustrates seven dielectric layers 12 and seven redistribution layers 12a, more or fewer dielectric layers 12 and redistribution layers 12a are within the contemplated scope of disclosure.

After the uppermost redistribution layer 12a is deposited, an upper surface of the back-side RDL interposer portion 21 may then be planarized (e.g., by wet etching, drying etching, chemical mechanical polishing (CMP), etc.). The planarization may be performed to make an upper surface of the uppermost redistribution layer 12a substantially coplanar with an upper surface of the uppermost dielectric layer 12. The formation of the back-side RDL interposer portion 21 completes the formation of the interposer 20.

FIG. 3E is a vertical cross-sectional view of an intermediate structure including the interposer 20 on a second carrier substrate 2 according to one or more embodiments. The second carrier substrate 2 may be substantially similar to the first carrier substrate 1.

The intermediate structure in FIG. 3E may be formed by applying an adhesive to the back-side RDL interposer portion 21 similar to the adhesive described above with the first carrier substrate 1. The second carrier substrate 2 may then be placed on the adhesive and adhered to the back-side RDL interposer portion 21 of the interposer 20. The intermediate structure may then be flipped and the second carrier substrate 2 placed on a flat surface such as a table or workbench. The first carrier substrate 1 may then be removed from the front-side RDL interposer portion 23 by decomposing (e.g., using UV light, heat, etc.) the adhesive adhering to the first carrier substrate 1 to the front-side RDL interposer portion 23.

FIG. 3F is a vertical cross-sectional view of an intermediate structure including the first semiconductor dies 141 on the interposer 20 according to one or more embodiments. The first semiconductor dies 141 may be mounted concurrently on the interposer 20 in the same process. The first semiconductor dies 141 may be mounted on the interposer 20 so as to be separated by the die-to-die gap G_{D2D} extending longitudinally in the y-direction and having a width in the x-direction in a range from 1 μm to 1000 μm (e.g., about 100 μm).

Each of the first semiconductor dies 141 may be bonded to the interposer 20 by one or more of the microbumps 128. In at least one embodiment, the microbumps 128 may include a two-dimensional array of microbumps 128, and each of the first semiconductor dies 141 may be attached to the redistribution layers 12 in the front-side RDL interposer portion 23 by chip connection (C2) bonding, (e.g., solder bonding). A C2 bonding process that reflows the solder portions of the microbumps 128 may be performed after the microbumps 128 on the first semiconductor dies 141 are disposed over corresponding redistribution layers 12a in the upper surface of the front-side RDL interposer portion 23. The microbumps 128 (through the redistribution layers 12a) may electrically couple the first semiconductor dies 141 to the microbumps 228 and the LSI die 200. The microbumps 128 (through the redistribution layers 12a) may also electrically couple the first semiconductor dies 141 to the microbumps 328 and the additional elements 240.

FIG. 3G is a vertical cross-sectional view of an intermediate structure including the package underfill layer 129 according to one or more embodiments. The package underfill layer 129 may be applied by depositing and/or injecting an epoxy-based polymeric material onto the front-side RDL interposer portion 23. The epoxy-based polymeric material may be applied on the front-side RDL interposer portion 23 so as to be formed under the first semiconductor dies 141 and around the microbumps 128. In at least one embodiment, the epoxy-based polymeric material may fill substantially all of the space between the first semiconductor dies 141 and the front-side RDL interposer portion 23. The epoxy-based polymeric material may also fill substantially all of the die-to-die gaps G_{D2D} between the first semiconductor dies 141. The package underfill layer 129 may then be cured, for example, in a box oven for about 90 minutes at about 150° C. to provide the package underfill layer 129 with a sufficient stiffness and mechanical strength.

FIG. 3H illustrates a vertical cross-sectional view of an intermediate structure including the upper molding layer 127 according to one or more embodiments. The upper molding layer 127 may be formed by dispensing a liquid molding material (e.g., EMC, epoxy molding material) onto the intermediate structure of FIG. 3G by a suitable dispensing tool. The liquid molding material may be dispensed onto the intermediate structure so as to have a height greater than the height of the semiconductor die upper surface 140a (e.g., an over-molding process).

In at least one embodiment, a dispensing of the liquid molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the liquid molding material based on various input parameters. The input parameters may include, for example, a size of the interposer 20, sizes of the first semiconductor dies 141, etc.

In at least one embodiment, the liquid molding material may include a capillary material (e.g., capillary underfill type material). The liquid molding material may have a low viscosity. In particular, the viscosity may be less than about 5,000 cP at 10 rpm. In at least one embodiment, the liquid molding material may include a low-viscosity suspension of thermally conductive material (e.g., metal, metal oxide) in prepolymer. The low viscosity may help to facilitate transport of the liquid molding material around the first semiconductor dies 141. The low viscosity may also help to avoid the formation of voids in the upper molding layer 127. In at least one embodiment, the upper molding layer 127 may be substantially free of voids.

After the upper molding layer 127 has been adequately cured, the upper molding layer 127 may be planarized so as to make the upper surface of the upper molding layer 127 to be substantially coplanar with the semiconductor die upper surface 140a. The upper molding layer 127 may be planarized, for example, by grinding, chemical mechanical polishing (CMP) or other suitable planarization technique to form the substantially planar upper surface S2 constituted by the upper surface of the upper molding layer 127 and the semiconductor die upper surface 140a. The formation of the substantially planar upper surface S2 may complete the formation of the upper molded structure 30 on the interposer 20.

FIG. 3I is a vertical cross-sectional view of an intermediate structure including the interposer 20 and the upper molded structure 30 on a third carrier substrate 3 according to one or more embodiments. The third carrier substrate 3 may be substantially similar to the first carrier substrate 1 and second carrier substrate 2.

The intermediate structure in FIG. 3I may be formed by applying an adhesive to the substantially planar upper surface S2 of the upper molded structure 30 similar to the adhesive described above with the first carrier substrate 1. The third carrier substrate 3 may then be placed on the adhesive and adhered to the substantially planar upper surface S2. The intermediate structure may then be flipped and the third carrier substrate 3 placed on a flat surface such as a table or workbench. The second carrier substrate 2 may then be removed from the back-side RDL interposer portion 21 by decomposing (e.g., using UV light, heat, etc.) the adhesive adhering to the second carrier substrate 2 to the back-side RDL interposer portion 21.

FIG. 3J illustrates a vertical cross-sectional view of an intermediate structure including the substrate portions 110, according to one or more embodiments. All of the substrate portions 110 including the substrate portions 110A, 110B and 110C may be mounted concurrently on the back-side RDL interposer portion 21 of the interposer 20 in the same process. The substrate portions 110 may be mounted so as to have a substantially coplanar surface away from the interposer 20. The substrate portions 110 may be mounted on the back-side RDL interposer portion 21 so as to be separated by the gap G1 extending longitudinally in the y-direction and having a width in the x-direction in a range from 1 μm to 1000 μm (e.g., about 100 μm).

Each of the substrate portions 110 may be bonded to the back-side RDL interposer portion 21 by one or more of the microbumps 28. In at least one embodiment, the microbumps 28 may include a two-dimensional array of microbumps 28, and each of the substrate portions 110 may be attached to the redistribution layers 12 in the back-side RDL interposer portion 21 by chip connection (C2) bonding, (e.g., solder bonding). A C2 bonding process that reflows the solder portions of the microbumps 28 may be performed after the microbumps 28 on the substrate portions 110 are disposed over corresponding redistribution layers 12a in the upper surface of the back-side RDL interposer portion 21. The microbumps 28 through the redistribution layers 12a in the back-side RDL interposer portion 21, the through vias 206 in the molded interposer portion 22, the redistribution layers 12a in the front-side RDL interposer portion 23 and the microbumps 128, may electrically couple the substrate portions 110 to the first semiconductor dies 141.

An optional underfill layer (not shown) may be formed around the microbumps 28. The optional underfill layer may be applied by depositing and/or injecting an epoxy-based polymeric material onto the back-side RDL interposer portion 21. The epoxy-based polymeric material may be applied on the back-side RDL interposer portion 21 so as to be formed under the substrate portions 110 and around the microbumps 28. In at least one embodiment, the epoxy-based polymeric material may fill substantially all of the space between the substrate portions 110 and the back-side RDL interposer portion 21. The epoxy-based polymeric material may also fill substantially all of the gaps G1 between the substrate portions 110. The underfill layer may then be cured, for example, in a box oven for about 90 minutes at about 150° C. to provide the underfill layer with a sufficient stiffness and mechanical strength.

It should be noted that there may be several alternative methods of connecting the substrate portions 110 to the back-side RDL interposer portion 21. In particular, the substrate portions 110 may be connected to the back-side RDL interposer portion 21 by solder regions/joints (e.g., microbumps, C4 bumps, etc.) prior to mounting the the components 41 and connectors 42. There may be several alternative configurations of those solder regions/joints (e.g., prior to mounting the bottom components 41 and connectors 42). In a first alternative, solder regions/balls may be pre-formed on the back-side RDL interposer portion 21 of the interposer 20 (e.g., F/O wafer). In a second alternative, the solder regions/balls may be pre-formed on the substrate portions 110 (or dummy units in place of the substrate portions 110). In a third alternative, the solder regions/balls may be pre-formed on both the back-side RDL interposer portion 21 and the substrate portions 110 (or dummy units in place of the substrate portions 110). In a fourth alternative, there may be some combination of the first, second and third alternatives.

FIG. 3K illustrates a vertical cross-sectional view of an intermediate structure including the lower molding layer 27 according to one or more embodiments. The lower molding layer 27 may be formed by dispensing a liquid molding material (e.g., EMC, epoxy molding material) onto the intermediate structure of FIG. 3J by a suitable dispensing tool. The liquid molding material may be substantially the same as the liquid molding material used to form the upper molding layer 127 described above. The liquid molding material may be dispensed onto the intermediate structure so as to have a height greater than the height of the substrate portions 110 (e.g., an overmolding process). The liquid molding material may be dispensed in a manner similar to the manner described above with respect to the upper molding layer 127.

After the lower molding layer 27 has been adequately cured, the lower molding layer 27 may be planarized so as to make a surface of the lower molding layer 27 away from the interposer 20 to be substantially coplanar with a surface of the substrate portions 110. The lower molding layer 27 may be planarized, for example, by grinding, chemical mechanical polishing (CMP) or other suitable planarization technique to form the substantially planar lower surface S1 constituted by the surface of the lower molding layer 27 and the surface of the substrate portions 110. The formation of the substantially planar lower surface S1 may complete the formation of the lower molded structure 10 on the interposer 20.

It should be noted that the lower molding layer 27 may be formed by a dispensing process that avoid the need for a planarization process so as to form the substantially planar lower surface S1. In particular, the liquid molding material may be dispensed onto the intermediate structure so as to have a height that is substantially coplanar with the height of the substrate portions 110. In that case, no planarization process may be required to form the substantially planar lower surface S1.

FIG. 3L illustrates a vertical cross-sectional view of an intermediate structure including the components 41 and connectors 42, according to one or more embodiments. All of the components 41 and connectors 42 may be mounted concurrently on the lower molded structure 10 in the same process. The components 41 and connectors 42 may be mounted so as to have a substantially coplanar surface away from the lower molded structure 10. The components 41 and connectors 42 may be mounted on the substantially planar lower surface S1 so as to be separated by the gap G40 extending longitudinally in the y-direction and having a width in the x-direction in a range from 100 μm to 2000 μm (e.g., about 500 μm).

Each of the components 41 and connectors 42 may be bonded to the substantially planar lower surface S1 by the microbumps 428. In at least one embodiment, the microbumps 428 may include a two-dimensional array of microbumps 428. Each of the components 41 and connectors 42 may be attached to the substrate lower bonding pads 116a of the substrate portions 110 in the lower molded structure 10 by chip connection (C2) bonding, (e.g., solder bonding) (e.g., see FIG. 2B). A C2 bonding process that reflows the solder portions of the microbumps 428 may be performed after the microbumps 428 are disposed over corresponding lower bonding pads 116a of the substrate portions 110 in the lower molded structure 10. The microbumps 428 may thereby electrically couple the components 41 and connectors 42 to the substrate portions 110.

An optional underfill layer (not shown) may be formed around the microbumps 428. The optional underfill layer may be applied by depositing and/or injecting an epoxy-based polymeric material onto the substantially planar lower surface S1. The epoxy-based polymeric material may be applied on the substantially planar lower surface S1 so as to be formed under the components 41 and connectors 42 and around the microbumps 428. In at least one embodiment, the epoxy-based polymeric material may fill substantially all of the space between the substantially planar lower surface S1 and the components 41 and connectors 42. The epoxy-based polymeric material may also fill substantially all of the gaps G40 between the components 41 and connectors 42. The underfill layer may then be cured, for example, in a box oven for about 90 minutes at about 150° C. to provide the underfill layer with a sufficient stiffness and mechanical strength.

It should be noted that there may be several alternative methods of connecting the components 41 and connectors 42 to the lower molded structure 10. In particular, solder regions/joints (e.g., microbumps, C4 bumps, etc.) for connecting the components 41 and connectors 42 to the lower molded structure 10 may be formed prior to mounting the the components 41 and connectors 42. There may be several alternative configurations of those solder regions/joints (e.g., prior to mounting the bottom components 41 and connectors 42). In a first alternative, solder regions/balls may be pre-formed on the substrate portions 110 (or dummy units in place of one or more of the substrate portions 110). In a second alternative, the solder regions/balls may be pre-formed on the components 41 and connectors 42 prior to mounting the components 41 and connectors 42. In a third alternative, the solder regions/balls may be pre-formed on both the substrate portions 110 (or dummy units in place of the substrate portions 110) and the components 41 and connectors 42. In a fourth alternative, there may be some combination of the first, second and third alternatives.

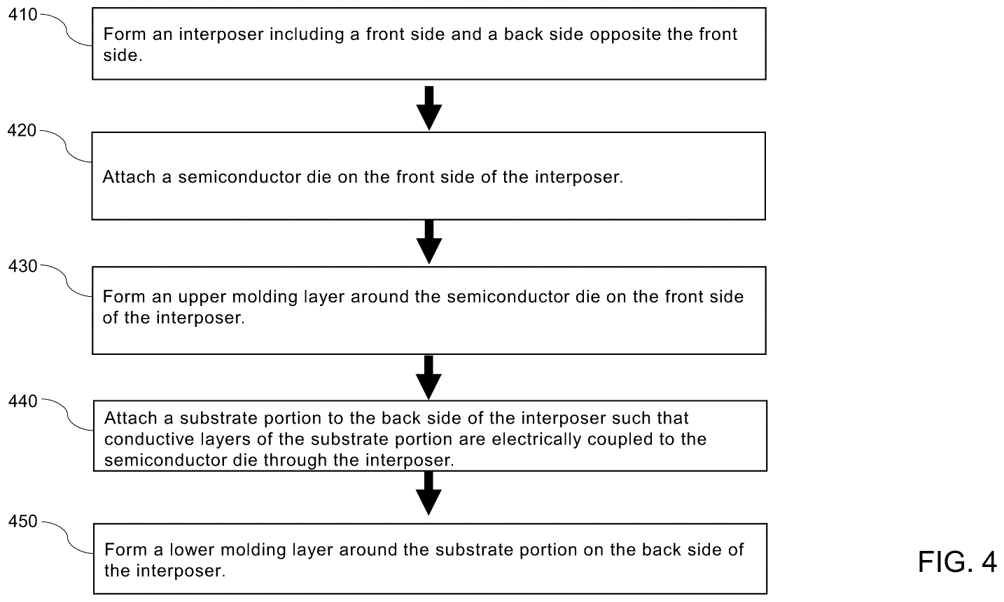

FIG. 4 is a flow chart illustrating a method of forming the package structure 100 according to one or more embodiments. Step 410 includes forming an interposer including a front side and a back side opposite the front side. Step 420 includes attaching a semiconductor die on the front side of the interposer. Step 430 includes forming an upper molding layer around the semiconductor die on the front side of the interposer. Step 440 includes attaching a substrate portion to the back side of the interposer such that conductive layers of the substrate portion are electrically coupled to the semiconductor die through the interposer. Step 450 includes forming a lower molding layer around the substrate portion on the back side of the interposer.

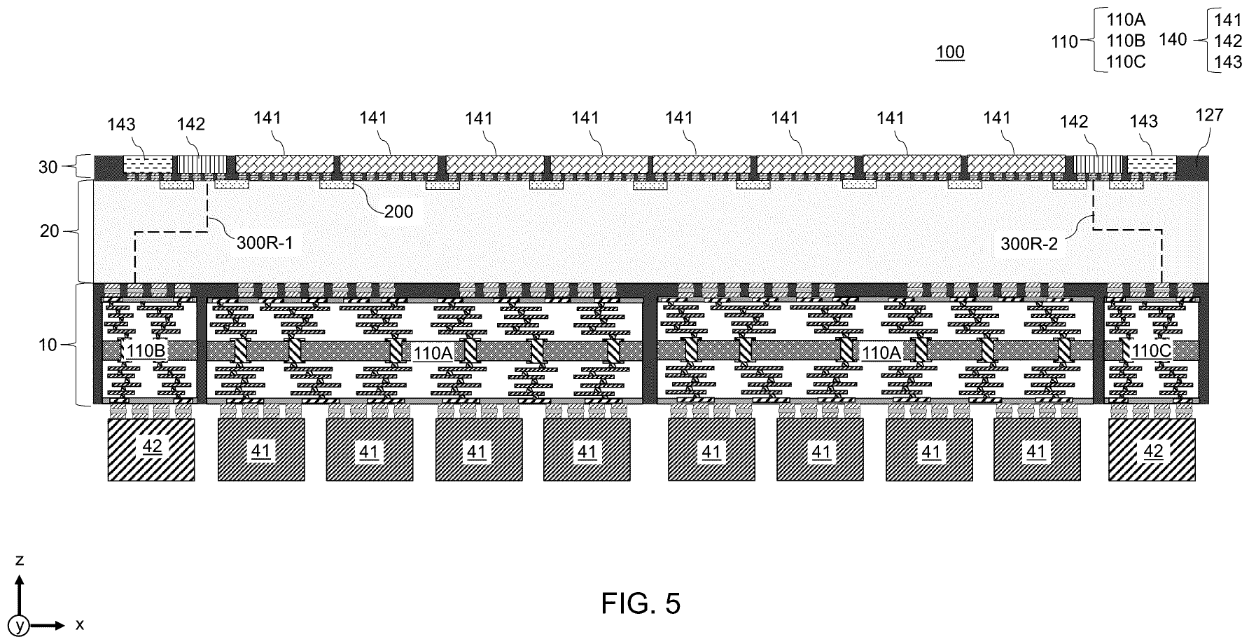

FIG. 5 is a vertical cross-sectional view of the package structure 100 having a first alternative design according to one or more embodiments. As illustrated in FIG. 5, in the first alternative design, the package structure 100 may include second semiconductor dies 142 and third semiconductor dies 143 in addition to the first semiconductor dies 141. The first semiconductor dies 141, second semiconductor dies 142 and third semiconductor dies 143 may be referred to collectively as semiconductor dies 140.

Each of the second semiconductor dies 142 and third semiconductor dies 143 may have a form and function similar to that of the first semiconductor die 141 as described above (e.g., logic die, memory die, etc.). In at least one embodiment, the first semiconductor dies 141, second semiconductor dies 142 and third semiconductor dies 143 may have different functionalities. In at least one embodiment, the first semiconductor dies 141 may include a computing die with an advanced silicon node (e.g., N5 or below) which may consume more power, and the second semiconductor dies 142 may include a chiplet input/output (I/O) die with a matured silicon node (e.g., N28 or above). In at least one embodiment, the third semiconductor dies 143 may include high-bandwidth memory (HBM) dies. The first semiconductor dies 141, second semiconductor dies 142 and third semiconductor dies 143 may be interconnected, for example, by one or more LSI dies 200 in the interposer 20 (e.g., in the molded interposer portion 22).

The substrate portions 110 may be configured with one or more routing functionalities for connecting the components 41 and connectors 42 to one or more of the semiconductor dies 140. For example, as illustrated in FIG. 5, the substrate portion 110B may be configured to route data, instructions, etc. by routing path 300R-1 through the interposer 20 to a second semiconductor die 142. The substrate portion 110C may be configured to route data, instructions, etc. by routing path 300R-2 through the interposer 20 to another second semiconductor die 142, and so on.

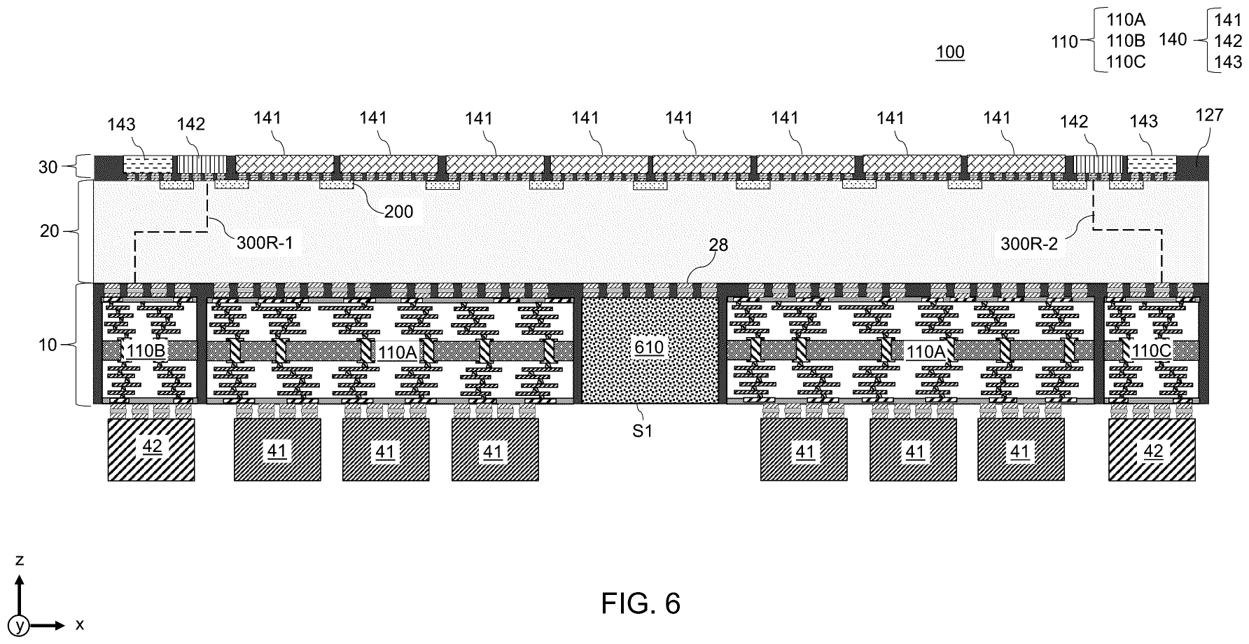

FIG. 6 is a vertical cross-sectional view of the package structure 100 having a second alternative design according to one or more embodiments. As illustrated in FIG. 6, in the second alternative design, the package structure 100 may include a dummy unit 610 (e.g., dummy die) in the lower molded structure 10. The dummy unit 610 may be included in the lower molded structure 10 in to provide additional rigidity to the lower molded structure 10 and structural support to the package structure 100. It should be noted that no components 41 or connectors 42 may be connected to the dummy unit 610.

In addition, the dummy unit 610 may be connected to the interposer 20 by the microbumps 28 or by other means such as an adhesive. A surface of the dummy unit 610 opposite the interposer 20 may constitute a portion of the substantially planar lower surface S1 of the lower molded structure 10. Further, while the dummy unit 610 in shown in FIG. 6 to be located near a center of the package structure 100 in the x-direction, the dummy unit 610 may be located anywhere in the lower molded structure 10. In at least one embodiment, the lower molded structure 10 may include a dummy unit 610 in place of the substrate portions 110B and 110C.

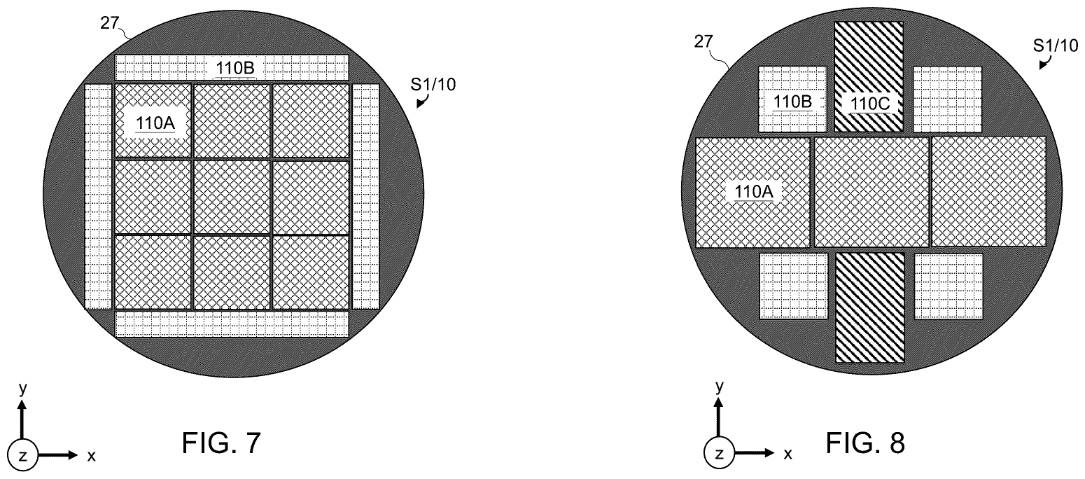

FIG. 7 is a bottom-up view of the substantially planar lower surface S1 of the lower molded structure 10 having a first alternative design, according to one or more embodiments. The components 41, connectors 42 and microbumps 428 have been omitted from FIG. 7 for ease of explanation.

As illustrated in FIG. 7, in the first alternative design, the lower molded structure 10 may include one or more substrate portions 110A and 110B in the lower molding layer 27. The substrate portions 110A may be arranged as an array of rows and columns in a central part of the lower molded structure 10. The substrate portions 110B may extend longitudinally along the outer sides of the array of substrate portions 110A. The substrate portions 110A and 110B may be cut (e.g., by dicing) and arranged so as to account for most of the substantially planar lower surface S1. In at least one embodiment, at least 70 percent of the substantially planar lower surface S1 may be constituted by the substrate portions 110A and 110B.

FIG. 8 is a bottom-up view of the substantially planar lower surface S1 of the lower molded structure 10 having a second alternative design, according to one or more embodiments. The components 41, connectors 42 and microbumps 428 have been omitted from FIG. 8 for ease of explanation.

As illustrated in FIG. 8, in the second alternative design, the lower molded structure 10 may include one or more substrate portions 110A, 110B and 110C in the lower molding layer 27. The substrate portions 110A may be arranged in a row in the x-direction. The substrate portions 110C may be located near a center of the lower molding layer in the x-direction and extend longitudinally in the y-direction on opposing sides of the substrate portions 110A. The substrate portions 110B may be located on opposing sides of the substrate portions 110C in the x-direction and on opposing sides of the substrate portions 110A in the y-direction. The substrate portions 110A, 110B and 110C may be cut (e.g., by dicing) and arranged so as to account for most of the substantially planar lower surface S1. In at least one embodiment, at least 70 percent of the substantially planar lower surface S1 may be constituted by the substrate portions 110A, 110B and 110C.

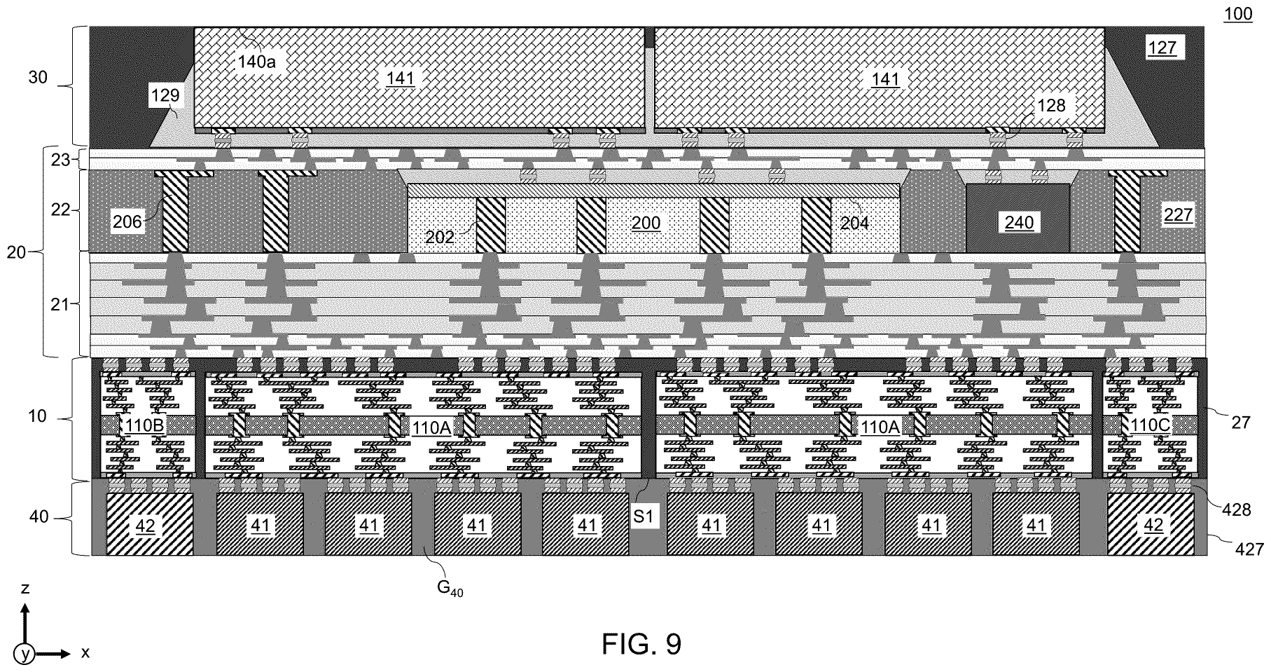

FIG. 9 is a vertical cross-sectional view of the package structure 100 having a third alternative design according to one or more embodiments. The third alternative design in FIG. 9 may be substantially similar to the original design in FIG. 1 but may also include an underlayer 40 on the lower molded structure 10. As illustrated in FIG. 9, the underlayer 40 may include an underlayer molding material 427 and the components 41 and connectors 42 may be formed in the underlayer molding material 427. The underlayer molding material 427 may be substantially the same as or different than the lower molding layer 27 and the upper molding layer 127. The underlayer molding material 427 may also be formed in a manner substantially the same as the lower molding layer 27 and the upper molding layer 127. In particular, the underlayer molding material 427 may be dispensed as liquid molding material around the components 41 and connectors 42. After curing, a surface of the underlayer molding material 427 may be planarized (e.g., by CMP) so that a surface of the underlayer molding material 427 is substantially coplanar with a surface of the components 41 and a surface of the connectors 42.

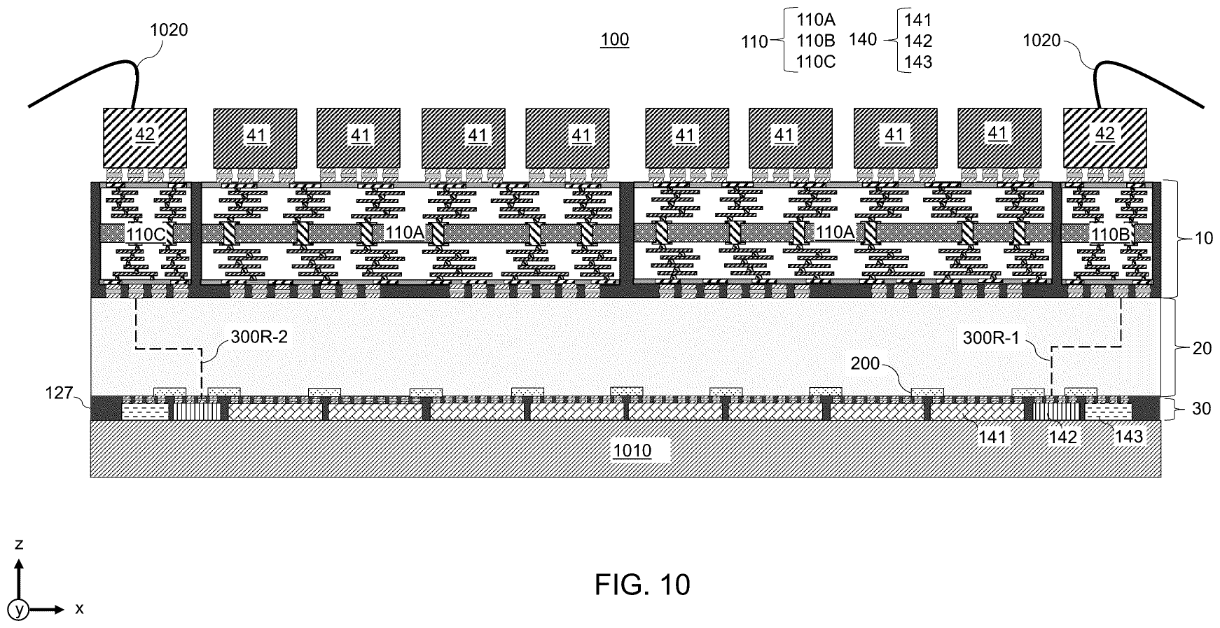

FIG. 10 is a vertical cross-sectional view of the package structure 100 having a fourth alterntative design according to one or more embodiments. The package structure 100 may have an inverted orientation. The package structure 100 may also include an optional cooling structure 1010 (e.g., cooling system, cooling device, etc.). The cooling structure 1010 may be placed on (e.g., attached to, mounted on, etc.) the upper molded structure 30. In particular, as illustrated in FIG. 10, the cooling structure 1010 may directly contact an upper surface of the upper molded structure 30.

In at least one embodiment the cooling structure 1010 may include an air-cooling device including a fan or other air-moving device to circulate air around the package structure 100 to dissipate heat. In at least one embodiment the cooling structure 1010 may include a liquid cooling device including a pump that pumps liquid coolant (e.g., water) around the package structure. In at least one embodiment the cooling structure 1010 may include a thermoelectric cooling device including a thermoelectric cooler that contacts the package structure 100 and pumps heat away from the package structure 100 and into a heatsink. In at least one embodiment, the cooling structure 1010 may include a heat pipe system including heat pipes containing a working fluid that cooling the package structure 100 by evaporation and condensation of the working fluid and transferring heat from the package structure to a heatsink. In at least one embodiment, the cooling structure 1010 may include phase-change cooling device including a refrigerant that is evaporated at the hot surface and then condensed at the cold surface to remove heat from the package structure 100.

The package structure 100 having the fourth alternative design may further include one or more conductors 1020 (e.g., metal wire, cable, non-wire connector, etc,) configured to electrically connect the package structure 100 to an external device such as a printed circuit board (PCB). In at least one embodiment, the conductors 1020 may connect to one or more of the connectors 42 of the package structure 100 to the external device. The semiconductor dies 140 of the package structure 100 may, therefore, be connected to the external device through the conductors 1020.

Referring to FIGS. 1-10, a package structure 100 may include an interposer 20 including a front side and a back side opposite the front side, an upper molded structure 30 on the front side of the interposer 20 and including an upper molding layer 127 and a semiconductor die 141 in the upper molding layer 127, and a lower molded structure 10 on the back side of the interposer 20 and including a lower molding layer 27 and a substrate portion 110A, 110B, 110C in the lower molding layer 27, wherein the substrate portion 110A, 110B, 110C may include conductive layers 114b, 116b electrically coupled to the semiconductor die 141 through the interposer 20.

In an embodiment, the interposer 20 may include a back-side redistribution layer (RDL) interposer portion 21, a molded interposer portion 22 on the back-side RDL interposer portion 21, and a front-side RDL interposer portion 23 on the molded interposer portion 22, wherein the upper molded structure 30 may be on the front-side RDL interposer portion 23. In one embodiment, the semiconductor die 141 may include a plurality of semiconductor dies 141 in the upper molding layer 127, and the molded interposer portion 22 may include a local silicon interconnect 200 connecting the plurality of semiconductor dies 141 through the front-side RDL interposer portion 23. In one embodiment, the substrate portion 110A, 110B, 110C may include a plurality of organic substrate portions 110A, 110B, 110C and the lower molding structure 10 may include a lower molding layer 27 that may be between the plurality of organic substrate portions 110A, 110B, 110C. In one embodiment, the lower molded structure 10 further may include a dummy unit 610 and the lower molding layer 27 may be between the plurality of organic substrate portions 110A, 110B, 110C and the dummy unit 610. In one embodiment, the plurality of organic substrate portions 110A, 110B, 110C may be separated by a first distance and the plurality of semiconductor dies 141 may be separated by a second distance less than the first distance. In one embodiment, the package structure 100 may further include a plurality of components 41 on the lower molded structure 10, wherein the plurality of components 41 may be electrically coupled to the substrate portion 110A, 110B, 110C and separated by a third distance greater than the second distance. In one embodiment, the package structure 100 may further include a connector 42 adjacent the plurality of components 41 on the lower molded structure 10 and electrically coupled to the semiconductor die 141 through the interposer 20. In one embodiment, the package structure 100 may further include an underlayer molding material on the lower molded structure 10, wherein the plurality of components 41 and the connector 42 may be located in the underlayer molding material. In one embodiment, the lower molded structure 10 has a first thickness and the interposer 20 has a second thickness less than the first thickness of the lower molded structure 10. In one embodiment, the upper molded structure 30 has a third thickness between the first thickness of the upper molded structure 30 and the second thickness of the interposer 20. In one embodiment, the substrate portion 110A, 110B, 110C may include a core 112 and a dielectric layer 114, 116 on the core 112, and the conductive layers 114b, 116b may include metal interconnect structures 114b, 116b in the dielectric layer 114, 116. In one embodiment, the dielectric layer 114, 116 may include at least one of a substrate upper dielectric layer 114 on a side of the core 112 adjacent the interposer 20, or a substrate lower dielectric layer 116 on a side of the core 112 opposite the interposer 20. In one embodiment, the package structure 100 may further include a cooling structure 1010 attached to the upper molded structure 30 and configured to cool the package structure 100.

Referring again to FIGS. 1-10, a method of forming a package structure 100 may include forming an interposer 20 including a front side and a back side opposite the front side, attaching a semiconductor die 141 on the front side of the interposer 20, forming an upper molding layer 127 around the semiconductor die 141 on the front side of the interposer 20, attaching a substrate portion 110A, 110B, 110C to the back side of the interposer 20 such that conductive layers 114b, 116b of the substrate portion 110A, 110B, 110C may be electrically coupled to the semiconductor die 141 through the interposer 20, and forming a lower molding layer 27 around the substrate portion 110A, 110B, 110C on the back side of the interposer 20. The forming of the interposer 20 may include forming a front-side redistribution layer (RDL) interposer portion 23 on a first carrier substrate 1, forming a molded interposer portion 22 on the front-side RDL interposer portion 23, and forming a back-side RDL interposer portion 21 on the molded interposer portion 22. In one embodiment, the method may further include bonding a second carrier substrate 2 to the back-side RDL interposer portion 21 and debonding the first carrier substrate 1 from the front-side RDL interposer portion 23, wherein the attaching of the semiconductor die 141 may include attaching the semiconductor die 141 to the front-side RDL interposer portion 23 and the forming of the upper molding layer 127 may include forming the upper molding layer 127 on the front-side RDL interposer portion 23, and planarizing an upper surface of the upper molding layer 127 to be substantially coplanar with an upper surface of the semiconductor die 141. In one embodiment, the method may further include bonding a third carrier substrate 3 to the upper molding layer 127 and debonding the second carrier substrate 2 from the back-side RDL interposer portion 21, wherein the attaching of the substrate portion 110A, 110B, 110C may include attaching the substrate portion 110A, 110B, 110C to the back-side RDL interposer portion 21 and the forming of the lower molding layer 27 may include forming a lower molding layer 27 on the back-side RDL interposer portion 21, and planarizing a surface of the lower molding layer 27 to be substantially coplanar with a surface of the substrate portion 110A, 110B, 110C. In one embodiment, the method may further include attaching a plurality of components 41 to the substrate portion 110A, 110B, 110C such that the plurality of components 41 may be electrically coupled to the interposer 20 through the substrate portion 110A, 110B, 110C.

Referring again to FIGS. 1-10, a package structure 100 may include an interposer 20 including a back-side redistribution layer (RDL) interposer portion 21 including a plurality of polymer layers 12 and a plurality of redistribution layers 12a in the plurality of polymer layers 12, a molded interposer portion 22 on the back-side RDL interposer portion 21 including a molding material layer and a local silicon interconnect (LSI) 200 in the molding material layer, and a front-side RDL interposer portion 23 on the molded interposer portion 22 and including a plurality of polymer layers 12 and a plurality of redistribution layers 12a in the plurality of polymer layers 12, an upper molded structure 30 on the front-side RDL interposer portion 23 of the interposer 20 including an upper molding layer 127, and a plurality of semiconductor dies 141 in the upper molding layer 127 and interconnected by the LSI 200 in the molded interposer portion 22, and a lower molded structure 10 on the back-side RDL interposer portion 21 of the interposer 20, including a lower molding layer 27, and a plurality of substrate portions 110A, 110B, 110C in the lower molding layer 27, including a plurality of metal interconnects electrically coupled to the plurality of semiconductor dies 141 through the plurality of redistribution layers 12a in the back-side RDL interposer portion 21 and the front-side RDL interposer portion 23.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
an interposer including a front side and a back side opposite the front side;
an upper molded structure on the front side of the interposer and comprising an upper molding layer and a semiconductor die in the upper molding layer; and
a lower molded structure on the back side of the interposer and comprising a lower molding layer and a substrate portion in the lower molding layer, wherein the substrate portion comprises conductive layers electrically coupled to the semiconductor die through the interposer.

2. The package structure of claim 1, wherein the interposer comprises:
a back-side redistribution layer (RDL) interposer portion;
a molded interposer portion on the back-side RDL interposer portion; and
a front-side RDL interposer portion on the molded interposer portion, wherein the upper molded structure is on the front-side RDL interposer portion.

3. The package structure of claim 2, wherein the semiconductor die comprises a plurality of semiconductor dies in the upper molding layer, and the molded interposer portion comprises a local silicon interconnect connecting the plurality of semiconductor dies through the front-side RDL interposer portion.

4. The package structure of claim 3, wherein the substrate portion comprises a plurality of organic substrate portions and the lower molding layer is between the plurality of organic substrate portions.

5. The package structure of claim 4, wherein the lower molded structure further comprises a dummy unit and the lower molding layer is between the plurality of organic substrate portions and the dummy unit.

6. The package structure of claim 4, wherein the plurality of organic substrate portions are separated by a first distance and the plurality of semiconductor dies are separated by a second distance less than the first distance.

7. The package structure of claim 6, further comprising:
a plurality of components on the lower molded structure, wherein the plurality of components are electrically coupled to the substrate portion and separated by a third distance greater than the second distance.

8. The package structure of claim 7, further comprising:
a connector adjacent the plurality of components on the lower molded structure and electrically coupled to the semiconductor die through the interposer.

9. The package structure of claim 8, further comprising:
an underlayer molding material on the lower molded structure, wherein the plurality of components and the connector are located in the underlayer molding material.

10. The package structure of claim 1, wherein the lower molded structure has a first thickness and the interposer has a second thickness less than the first thickness of the lower molded structure.

11. The package structure of claim 10, wherein the upper molded structure has a third thickness between the first thickness of the upper molded structure and the second thickness of the interposer.

12. The package structure of claim 1, wherein the substrate portion comprises a core and a dielectric layer on the core, and the conductive layers comprise metal interconnect structures in the dielectric layer.

13. The package structure of claim 12, wherein the dielectric layer comprises at least one of:
a substrate upper dielectric layer on a side of the core adjacent the interposer; or
a substrate lower dielectric layer on a side of the core opposite the interposer.

14. The package structure of claim 1, further comprising:
a cooling structure attached to the upper molded structure and configured to cool the package structure.

15. A method of forming a package structure, the method comprising:
forming an interposer including a front side and a back side opposite the front side;
attaching a semiconductor die on the front side of the interposer;
forming an upper molding layer around the semiconductor die on the front side of the interposer;
attaching a substrate portion to the back side of the interposer such that conductive layers of the substrate portion are electrically coupled to the semiconductor die through the interposer; and
forming a lower molding layer around the substrate portion on the back side of the interposer.

16. The method of claim 15, wherein the forming of the interposer comprises:
forming a front-side redistribution layer (RDL) interposer portion on a first carrier substrate;
forming a molded interposer portion on the front-side RDL interposer portion; and
forming a back-side RDL interposer portion on the molded interposer portion.

17. The method of claim 16, further comprising:
bonding a second carrier substrate to the back-side RDL interposer portion and debonding the first carrier substrate from the front-side RDL interposer portion, wherein the attaching of the semiconductor die comprises attaching the semiconductor die to the front-side RDL interposer portion and the forming of the upper molding layer comprises forming the upper molding layer on the front-side RDL interposer portion; and
planarizing an upper surface of the upper molding layer to be substantially coplanar with an upper surface of the semiconductor die.

18. The method of claim 17, further comprising:
bonding a third carrier substrate to the upper molding layer and debonding the second carrier substrate from the back-side RDL interposer portion, wherein the attaching of the substrate portion comprises attaching the substrate portion to the back-side RDL interposer portion and the forming of the lower molding layer comprises forming a lower molding layer on the back-side RDL interposer portion; and
planarizing a surface of the lower molding layer to be substantially coplanar with a surface of the substrate portion.

19. The method of claim 18, further comprising:
attaching a plurality of components to the substrate portion such that the plurality of components are electrically coupled to the interposer through the substrate portion.

20. A package structure, comprising:
an interposer comprising:
a back-side redistribution layer (RDL) interposer portion including a plurality of polymer layers and a plurality of redistribution layers in the plurality of polymer layers;
a molded interposer portion on the back-side RDL interposer portion, comprising a molding material layer and a local silicon interconnect (LSI) in the molding material layer; and
a front-side RDL interposer portion on the molded interposer portion and including a plurality of polymer layers and a plurality of redistribution layers in the plurality of polymer layers;
an upper molded structure on the front-side RDL interposer portion of the interposer, comprising:
an upper molding layer; and
a plurality of semiconductor dies in the upper molding layer and interconnected by the LSI in the molded interposer portion; and
a lower molded structure on the back-side RDL interposer portion of the interposer, comprising:
a lower molding layer; and
a plurality of substrate portions in the lower molding layer, comprising a plurality of metal interconnects electrically coupled to the plurality of semiconductor dies through the plurality of redistribution layers in the back-side RDL interposer portion and the front-side RDL interposer portion.
